(19) United States
(12) Patent Application Publication
(10) Pub. No.: US 2012/0160557 A1
(43) Pub. Date: Jun. 28, 2012

(54) STRUCTURE FOR MINIMIZING DETERIORATION OF THERMAL AND MECHANICAL PROPERTIES OF ELECTRICAL COMPONENTS DUE TO ELEVATED TEMPERATURES

(75) Inventors: Tsukasa YAMADA, Tokyo (JP); Takahiko NISHIYAMA, Tokyo (JP); Toyoki TANAKA, Tokyo (JP)

(73) Assignee: MITSUMI ELECTRIC CO., LTD., Tokyo (JP)

(21) Appl. No.: 13/332,554

(22) Filed: Dec. 21, 2011

(30) Foreign Application Priority Data
Dec. 24, 2010 (JP) 2010-287645
Sep. 30, 2011 (JP) 2011-218414

(51) Int. Cl. H05K 7/14; H05K 1/16; H05K 7/00; H05K 1/00

(52) U.S. Cl. 174/544; 174/250; 174/260; 174/520

(57) ABSTRACT

A structure including: a first part including an electrode pad in a predetermined area on a surface; a second part that is bonded to the first part using an adhesive; and a board, including a terminal pad, to which the second part is fixed, wherein the electrode pad and the terminal pad are ultrasonic-bonded, and the second part includes bosses on an area that overlaps the predetermined area in a bonding surface between the second part and the first part.

### CROSS-REFERENCE TO RELATED APPLICATION

The present application is based upon and claims the benefit of priority of Japanese Patent Application No. 2010-287645, filed on Dec. 24, 2010, and Japanese Patent Application No. 2011-218414, filed on Sep. 30, 2011, and the entire contents of the Japanese Patent Applications No. 2010-287645 and No. 2011-218414 are incorporated herein by reference.

### BACKGROUND OF THE INVENTION

1. Field of the Invention

The present invention relates to a structure for minimizing deterioration of thermal and mechanical properties of electrical components supported by the structure due to elevated temperatures. More particularly, the present invention relates to a structure in which a first part having an electrode pad in a predetermined area on the surface is bonded to a second part, the second part is fixed on a board having a terminal pad, and the electrode pad and the terminal pad are ultrasonic-bonded.

2. Description of the Related Art

As a conventional technique, Japanese Laid-Open Patent Application No. 2001-249300 discloses an optical scanner for rotating a mirror part that reflects an incident light around a rotation axis so as to perform scanning with a reflected light. In the optical scanner, band-like concave parts are formed along a direction perpendicular to the rotation axis on the backside of the mirror part. Accordingly, the weight of the mirror part is reduced, and the optical scanner is less subject to mirror bending, so that the speed of operation increases by increasing the amplitude of the mirror part without deterioration of resonance frequency.

However, even though various schemes are devised for the structure of the mirror part, it is necessary to provide a packaged product in which a structure including the mirror part is electrically connected for providing an optical scanner as an actual product. In order to achieve suitable packaging for providing such a product, it is necessary to bond a structure including the mirror part to a support member and to perform wire bonding between the structure and a board by placing the support member on the board. At this time, there may a case in which stress is applied to the structure due to a difference of thermal expansion coefficients between materials when temperature rises, so that various problems such as deterioration of operation characteristics may occur when performing such packaging.

### SUMMARY OF THE INVENTION

Accordingly, an object of an embodiment of the present invention is to provide a structure that prevents deterioration of characteristics due to temperature increase from occurring and that enables reliable ultrasonic bonding when performing packaging of the structure such as an optical scanning apparatus and the like.

According to an embodiment, there is provided a structure including:
a first part including an electrode pad in a predetermined area on a surface;
a second part that is bonded to the first part using an adhesive; and
a board, including a terminal pad, to which the second part is fixed,
wherein the electrode pad and the terminal pad are ultrasonic-bonded, and
the second part includes bosses on an area that overlaps the predetermined area in a bonding surface between the second part and the first part.

According to another embodiment, there is provided a structure including:
a first part including an electrode pad in a predetermined area on a surface; and
a second part that includes a terminal pad and that is bonded to the first part using an adhesive;
wherein the electrode pad and the terminal pad are ultrasonic-bonded,
   the second part includes:
      a bonding member on an area that overlaps the predetermined area in a bonding surface between the second part and the first part, and
      an attaching part configured to protrude with respect to the first part and to form a plane joint surface that is an upper surface of the attaching part.

Other objects and further features of the present invention will be apparent from the following detailed description when read in conjunction with the accompanying drawings.

### BRIEF DESCRIPTION OF THE DRAWINGS

FIG. 1 is a diagram showing an example of a configuration of an element 40 in a structure of an embodiment 1;

FIG. 2 is a diagram showing an example of a configuration of a fixing support member 50 of the structure according to the embodiment 1;

FIG. 3A is a diagram showing a shape of the bosses 51 according to a first example of the fixing support member 50 of the structure of the embodiment 1;

FIG. 3B is a diagram showing a configuration of bosses 51A according to a second example of the fixing support member 50;

FIG. 3C is a diagram showing a configuration of bosses 51B according to a third example of the fixing support member 50;

FIG. 4A is a perspective view of the structure of the embodiment 1 viewed from the side of the element 40;

FIG. 4B is a perspective view of the structure of the embodiment 1 viewed from the side of the fixing support member 50;

FIG. 4C is a side view of the structure of the embodiment 1;

FIG. 5A is a perspective view showing an example of a configuration in which the fixing support member 50 and the element 40 are fixed on the board 70;

FIG. 5B is a diagram showing an example of a sectional configuration of the structure around the bosses 51;

FIG. 6A is a diagram showing a packaging finished state of the structure of the embodiment 1;

FIG. 6B is a sectional side perspective view of the packaged state of the structure of the embodiment 1;

FIG. 6C is a side section view of the packaged state of the structure of the embodiment 1;

FIG. 6D is a perspective view showing a configuration of the backside of the cover 90;

FIG. 6E is a diagram showing the backside of the board 70;

FIG. 7A is a perspective view showing a configuration of the element 41;

FIG. 7B is a perspective view showing an example of a configuration of an element 42 in a structure of the embodiment 2;

FIG. 8 is a diagram showing the fixing support member 53 of the structure of the embodiment 2 with the element 42;

FIG. 9A is a perspective view of the structure of the embodiment 2 in which the element 42 and the fixing support member 53 are bonded so that they are integrated, viewed from the side of the element 42;

FIG. 9B is a perspective view of the structure of the embodiment 2 in which the element 42 and the fixing support member 53 are bonded so that they are integrated, viewed from the side of the fixing support member 53;

FIG. 9C is a side view of the structure of the embodiment 2 in which the element 42 and the fixing support member 53 are bonded so that they are integrated;

FIG. 10 is a perspective view showing a structure of the embodiment 2 in which the fixing support member 53 and the element 42 are fixed on a board 73;

FIG. 11A is a perspective view showing a whole configuration of a packaging finished state of the structure of the embodiment 2;

FIG. 11B is a perspective view showing a sectional configuration of the structure of the embodiment 2 after packaging is finished;

FIG. 11C is a side section view showing a sectional configuration of the structure of the embodiment 2 after packaging is finished;

FIG. 11D is a diagram showing a configuration of the backside of the cover 93;

FIG. 11E is a diagram showing the backside of the structure of the embodiment 2 after packaging is finished;

FIG. 12A is a diagram showing a configuration similar to the element 40 of the structure of the embodiment 1;

FIG. 12B is a diagram showing an example of a configuration of the element 43 of the structure of the embodiment 3;

FIG. 13 is a diagram showing the fixing support member 56 of the structure of the embodiment 2 with the element 43;

FIG. 14A is a perspective view of the structure of the embodiment 3 in which the element 43 and the fixing support member 56 are bonded, viewed from the side of the element 43;

FIG. 14B is a perspective view of the structure of the embodiment 3 in which the element 43 and the fixing support member 56 are bonded, viewed from the side of the fixing support member 56;

FIG. 14C is a side view of the structure of the embodiment 3 in which the element 43 and the fixing support member 56 are bonded;

FIG. 15 is a diagram showing the structure of the embodiment 3 in which the fixing support member 56 and the element 43 are fixed on a board;

FIG. 16A is a perspective view showing the whole structure of the embodiment 3 after packaging is finished;

FIG. 16B is a perspective view showing a sectional configuration of the structure of the embodiment 3 after packaging is finished;

FIG. 16C is a side section view showing a sectional configuration of the structure of the embodiment 3 after packaging is finished;

FIG. 16D is a diagram showing a configuration of the backside of the cover 96;

FIG. 16E is a diagram showing an example of a configuration of the backside of the structure of the embodiment 3 after packaging is finished;

FIG. 17 is a diagram showing an example of the structure of the embodiment 4;

FIG. 18A is a top perspective view of the package of the structure of the embodiment 4;

FIG. 18B is a bottom perspective view of the package of the structure of the embodiment 4;

FIG. 19A is a top view of a package 110;

FIG. 19B is a side view of the package 110;

FIG. 19C is a front view of the package 110;

FIG. 19D is a bottom view of the package 110;

FIG. 20 is a diagram showing the structure of the embodiment 4;

FIG. 21A is a top view of the structure of the embodiment 4;

FIG. 21B is a front view of the structure of the embodiment 4;

FIG. 22A is a perspective view of the inside of the state in which the structure is attached to the attachment board;

FIG. 22B is a perspective view of the outside of the state in which the structure is attached to the attachment board.

FIG. 23A is an exploded perspective view, viewed from the inside, of the state in which the structure of the embodiment 4 is attached to the attachment board;

FIG. 23B is an exploded perspective view, viewed from the outside, of the state in which the structure of the embodiment 4 is attached to the attachment board;

FIG. 24A is a diagram of an enlarged view of a part where the structure of the embodiment 4 is attached to the attachment board 140 of the cabinet 145;

FIG. 24B is a whole perspective view of an example in which the structure of the embodiment 4 is attached to the cabinet;

FIG. 24C is a backside perspective view of an example in which the structure of the embodiment 4 is attached to the cabinet;

FIG. 25A is a top perspective view of an example of the package of the structure of the embodiment 5;

FIG. 25B is a bottom perspective view of an example of the package of the structure of the embodiment 5;

FIG. 26A is a top view of the package of the structure in the embodiment 5;

FIG. 26B is a side view of the left side of the package of the structure of the embodiment 5;

FIG. 26C is a front view of the package of the structure of the embodiment 5; and

FIG. 26D is a bottom view of the package of the structure of the embodiment 5.

### DESCRIPTION OF THE PREFERRED EMBODIMENTS

Preferred embodiments of the present invention are described below with reference to the accompanying drawings.

### Outline of Embodiments

Before describing embodiments in detail, an outline of the embodiments is described below.

According to an embodiment, there is provided a structure including:
a first part (40, 42, 43) including an electrode pad (31, 35) in a predetermined area (32, 36) on a surface;
a second part (50, 53, 56) that is bonded to the first part using an adhesive (60, 61, 62); and
a board (70, 73, 76), including a terminal pad (71, 74, 77), to which the second part is fixed,
wherein the electrode pad and the terminal pad are ultrasonic-bonded, and
the second part includes bosses (51, 54, 57) on an area that overlaps the predetermined area in a bonding surface between the second part and the first part.

In the structure, three or more bosses may be provided on the bonding surface so as to support the first part. Also, a top end of each of the bosses may be shaped like a convex curved surface.

The adhesive may have a consistency by which, even though the first part or the second part is thermally-expanded or contracted, the adhesive absorbs stress due to a difference of thermal expansion and contraction to reduce the stress in the first part. An after-cured Shore hardness of the adhesive may be equal to or less than 200.

The second part may be transparent, and the adhesive may be cured by irradiation of ultraviolet light.

Also, the first part may be formed by a semiconductor and the second part may be a resin molding part.

In the structure, the first part may be an actuator or a sensor that mechanically operates, and the second part may include a stopper (52, 55, 58, 92, 95, 99) for shock resistance for the actuator or the sensor.

The structure may further include a cover (90, 93, 96) configured to cover the first part, the second part and the board, wherein the cover may include a stopper for shock resistance for the actuator or the sensor.

The first part may include a fixing frame (30) configured to surround a driving part of the actuator or the sensor, and the fixing frame may be bonded to the bonding surface of the second part.

The first part may include a fixing piece (34) configured to support a driving part of the actuator or the sensor with one side, and the fixing piece may be bonded to the bonding surface of the second part.

The first part may include a fixing member (37) configured to support a driving part (10, 20) of the actuator or the sensor by sandwiching the driving part from both sides, and the fixing member may be bonded to the bonding surface of the second part.

The actuator may be an optical scanning apparatus configured to perform scanning using a reflected light by fluctuating a mirror around an axis.

According to an embodiment, there is provided a structure including:
a first part (44) including an electrode pad (31) in a predetermined area (32) on a surface; and
a second part (110, 150) that includes a terminal pad (115, 155) and that is bonded to the first part using an adhesive;
wherein the electrode pad and the terminal pad are ultrasonic-bonded, and
   the second part includes: a bonding member (114, 154) on an area that overlaps the predetermined area in a bonding surface between the second part and the first part, and an attaching part (116, 156, 157) configured to protrude with respect to the first part and to form a plane joint surface that is an upper surface of the attaching part.

The attaching part and the terminal pad may be placed on a same straight line.

The terminal pad may be placed at a center portion of the second part in a shorter direction of the second part, and the attaching part may be placed so as to sandwich the terminal pad from both sides in the shorter direction. Also, the attaching part may be placed at four corners of the second part.

Also, the first part may be formed by a semiconductor, and the second part may be formed by ceramics.

The first part may be an actuator or a sensor that mechanically operates, and the first part may include a fixing member (37) configured to support a driving part (16, 24) of the actuator or the sensor by sandwiching the driving part from both sides, and the second part may include: a fixing part (113, 153) to which the fixing member of the first part is bonded; and a bottom part (111, 151) that is recessed with respect to the fixing part and that does not contact with the driving part.

The actuator may be an optical scanning apparatus configured to perform scanning using a reflected light by fluctuating a mirror (11) around an axis.

According to an embodiment, temperature characteristics of the structure can be improved, and driving can be performed stably even through temperature changes. Also, stable ultrasonic wire bonding becomes available.

### Embodiment 1

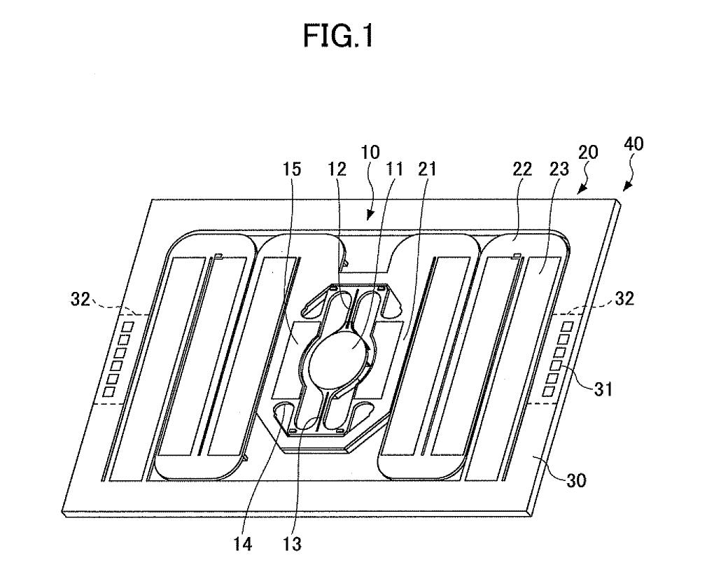

FIG. 1 is a diagram showing an example of a configuration of an element 40 in a structure of the embodiment 1. The element 40 is configured to be an actuator that functions as an optical scanning apparatus. The element 40 includes a horizontal driving part 10, a vertical driving part 20, and a fixing frame 30. The horizontal driving part 10 includes a mirror 11, a twisting beam 12, a slit 13, a horizontal driving beam 14, and a driving source 15. The vertical driving part 20 includes a movable frame 21, a vertical driving beam 22, and a driving source 23. The fixing frame 30 includes electrode pads 31, and an electrode pad forming area 32.

The element 40 fluctuates the mirror 11 in a horizontal direction and in a vertical direction so as to cause a light reflected from the mirror 11 to perform scanning so that an image is provided. For example, the element 40 is embedded in an electronic apparatus such as a mobile phone for projecting an image on a screen of the electronic apparatus.

Both sides of the mirror 11 are connected to the twisting beams 12 so as to be supported. The twisting beams 12 form a fluctuation axis (or a rotation axis) for fluctuating the mirror 11 in the horizontal direction. A structure may be adopted in which a slit 13 is formed in the twisting beams 12 so that linearity of resonance vibration may be improved. The twisting beams 12 are connected to horizontal driving beams 14 that are placed in the sides of the mirror 11 so as to sandwich the mirror 11. A driving source 15 including a piezoelectric element is provided on the surface of each horizontal driving beam 14. The driving source 15 is expanded and contracted by applying a voltage to the driving source 15 so that the horizontal driving beams 14 are resonantly vibrated up and down. Thus, the horizontal driving beams 14 fluctuate the mirror 11 in the horizontal direction using the twisting beams 12 as a fluctuation axis (or rotation axis). Accordingly, the reflected light of the mirror 11 can perform scanning in the horizontal direction. Also, each horizontal driving beam 14 is supported by a movable frame 21. Also, vertical driving beams 22 are connected to the outside of the movable frame 21. Each vertical driving beam 22 longitudinally extends in a direction parallel to the twisting beam 12. The vertical driving beam 22 connects to an adjacent vertical driving beam 22 in a direction perpendicular to the twisting beam 12 at an end part of the extending part. The vertical driving beams 22 as a whole extend while moving in a serpentine manner. That is, the vertical driving beams 22 as a whole have a zigzag shape, and an end opposite to the side of the movable frame 21 is connected to the inner end part of the fixing frame 30. Driving sources 23 including piezoelectric elements are provided on the surface of the vertical driving beams 22 at parts of a rectangular shape. By applying voltages of different polarities to adjacent driving sources 23, the driving sources 23 extend and contract so that warpage of the vertical driving beams 22 can be accumulated, and the movable frame 21 can be fluctuated in the vertical direction. That is, a fluctuation force is applied to the mirror 11 in the vertical direction via the movable frame 21. Also, for example, non-resonant vibration may be used for driving the vertical driving beams 22.

The fixing frame 30 supports the horizontal driving part 10 and the vertical driving part 20. That is, the vertical driving beams 22 are connected to and supported by the fixing frame 30, the movable frame 21 is connected to and supported by the vertical driving beams 22, the twisting beams 12 are connected to and supported by the horizontal driving beams 15, and the mirror 11 is connected to and supported by the twisting beams 12. Therefore, even when the horizontal driving part 10 and the vertical driving part 20 are vibrating, the fixing frame 30 fixedly supports the horizontal driving part 10 and the vertical driving part 20 while remaining still.

The fixing frame 30 includes electrode pads 31 that become voltage supplying sources to the driving sources 15 and 23. The driving sources 15 and 23 are electrically connected to the electrode pads 31 provided in the right and the left sides of the fixing frame 30, and are provided with voltages so as to perform driving in the horizontal direction and the vertical direction as mentioned above. Power may be supplied from an external part to the electrode pads 31. In FIG. 1, near a center part in each of the right and the left sides of the fixing frame 30, the electrode pads 31 are densely placed within an electrode pad forming area 32 of the fixing frame 30. By aggregating wiring portions into each of the right and the left parts, wiring connections to external parts and wiring connections to the driving beams 15 and 23 are simplified so that wiring work becomes easy.

In FIG. 1, although an example is described in which the element 40 is configured as an optical scanning apparatus, the structure of the embodiment 1 can be also applied to an actuator and a sensor that perform other mechanical operations. In addition, even in the case where the structure is configured as the optical scanning apparatus, various configurations can be applied as long as the structure includes the fixing frame 30 having the electrode pads 31.

In addition, the element 40 may be formed by a semiconductor such as silicon and the like. It is possible to fabricate a fine structure from a semiconductor board by using processing techniques of MEMS (Micro Electro Mechanical Systems). Therefore, the element 40 may be fabricated from the semiconductor substrate by using the MEMS technique. As to the semiconductor substrate, various semiconductor substrates may be used as long as the structure can be fabricated. For example, an SOI (Silicon On Insulator) may be used, the SOI (Silicon On Insulator) being made by sandwiching a silicon substrate with insulating oxidized films from both sides.

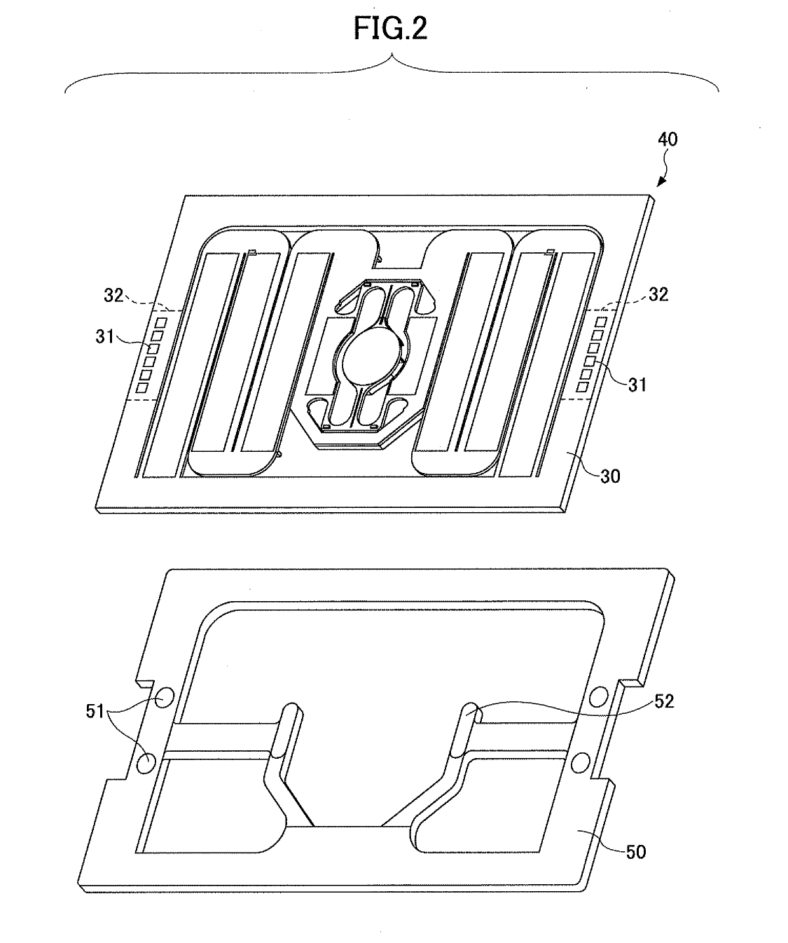

FIG. 2 is a diagram showing an example of a configuration of a fixing support member 50 of the structure according to the embodiment 1. In FIG. 2, an example of a configuration of the fixing support member 50 is shown with the element 40. The fixing support member 50 is a part used for fixing the fixing frame 30 of the element 40 to a package. The element 40 is bonded to the surface of the fixing support member 50. The fixing support member 50 is configured like a frame having a boundary length larger than the fixing frame 30 such that the fixing frame 30 can be placed on the surface and bonded.

The fixing support member 50 includes bosses 51 on the frame part. The frame part forms a bonding surface that is bonded to the lower surface of the fixing frame 30 of the element 40. The bosses 51 are provided on the bonding surface bonded to the element 40. Adhesive bonding between the element 40 and the fixing support member 50 is performed by applying an adhesive on a bonding surface of the fixing support member 50 or the element 40 and bonding them together. At the time, the adhesive is applied to areas including the periphery of the bosses 51 such that interstices between the fixing support member 50 and the element 40 are filled other than the part where the bosses 51 exist. As to the adhesive, various adhesives can be used. For example, a ultraviolet cure adhesive that is cured with irradiation of ultraviolet light may be used. Also, an adhesive that is cured by two-liquid reaction, heat, anaerobicity and humidity and the like may be used, so that various adhesives may be used. When the ultraviolet cure adhesive is used, it is preferable to use a ultraviolet-transmitting material such as a transparent member as the fixing support member 50, such that ultraviolet light can be irradiated to the adhesive through the fixing support member 50. For example, a transparent resin molding part made of an acrylic resin or a polycarbonate resin or the like may be used. When using other adhesives, it is not necessary to use a transparent fixing support member 50, and parts made of various materials may be used according to the usage.

The bosses 51 are placed such that the bosses 51 overlap the electrode pad forming areas 32 when the element 40 and the fixing support member 50 are bonded. That is, the bosses 51 are provided at positions corresponding to the electrode pads 31. After the element 40 and the fixing support member 50 are bonded and fixed, the structure is placed on a board, and ultrasonic bonding is performed for bonding the structure with terminal pads provided on the board. At that time, the bosses 51 placed at the above-mentioned positions prevent ultrasonic waves from escaping through the soft adhesive layer. Thus, since the bosses 51 are used when performing ultrasonic bonding for the electrode pads 31, the bosses 51 are provided at positions overlapping the electrode pad forming areas 32 such that the bosses 51 exist under the electrode pad forming areas 32.

As an example, if a soft adhesive is used in order to soften the stress occurred due to the difference of the thermal expansion coefficients, when ultrasonic wire bonding is performed, there may be a problem in which bonding between wires and electrode pads cannot be performed sufficiently since vibrations of the ultrasonic waves are absorbed by the soft adhesive so that the ultrasonic vibrations are not transmitted to the electrode pads sufficiently. On the other hand, according to the embodiment, the ultrasonic bonding can be performed properly.

It is preferable that three or more bosses 51 are provided on the bonding surface such that the element 40 can be positioned and supported. Accordingly, the bosses 51 function like a spacer, so that the element 40 can be positioned in a state where the element 40 is placed on the bosses 51. Although depending on the placement, when three or more bosses 51 are placed on the bonding surface, a state where the bosses 51 support the element 40 can be made. In this state, positioning for the height of the element 40 is unnecessary, so that only positioning for horizontal positions is necessary. Thus, it becomes possible to perform bonding processes easily. In the example shown in FIG. 2, two bosses 51 are provided in each of the right and the left sides. Since it is preferable to support the element 40 symmetrically in terms of balance, four bosses 51 in total may be provided in which two bosses are provided in each of the right and the left sides as shown in FIG. 2.

The fixing support member 50 includes a lower stopper 52 for shock resistance. Accordingly, even if the structure of the embodiment receives a shock due to falling and the like, the element 40 can be protected against the shock.

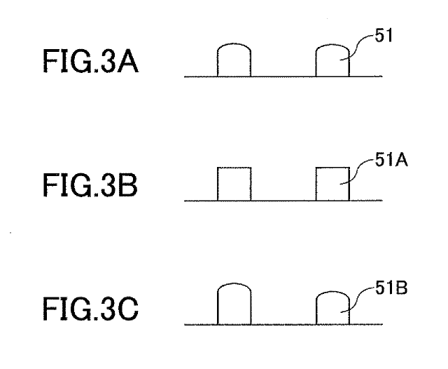

FIGS. 3A-3C are side views showing various examples of the configuration of the bosses 51 of the structure according to the embodiment 1. FIG. 3A is a diagram showing a shape of the bosses 51 according to a first example of the fixing support member 50 of the structure of the embodiment 1. As shown in FIG. 3A, each boss 51 has a shape in which the top part of the cylinder is formed like a upward convex curved surface. The curved surface may be a part of a sphere like a hemisphere, or may be another upward convex shape, for example. By forming the boss 51 such that the top part is shaped like an upward convex curved surface, the element 40 can be supported by minimum contact points. For example, even when the bosses 51 vary in height to some extent, point contact without constraints is realized between the fixing frame 30 and the bosses 51 by adopting the configuration of FIG. 3A. Thus, the element 40 can be supported without applying any excess stress to the element 40.

FIG. 3B is a diagram showing a configuration of a boss 51A according to a second example of the fixing support member 50. The boss 51A of the second example has a column shape in which the top surface is a plane. The boss 51A may have a shape of a cylinder or a prismatic column such as a triangular column and a rectangular column. In the case of the boss 51A of the second example, since it is necessary to keep the heights of the plural bosses 51A aligned accurately, it is required to accurately process the height of the bosses compared to the bosses of the first example.

FIG. 3C is a diagram showing a configuration of each boss 51B according to a third example of the fixing support member 50. The shape of each boss 51B of the third example is the same as the boss 51 of the first example. But, the bosses 51B of the third example are different from the bosses of the first example in that the adjacent bosses 51B in the right and the left vary in height. For example, in the case when it is required to fix and support the element 40 in a slanted state, the element 40 may be supported by using the bosses 51B of the third example. In the case where the bosses 51B are used, since the fixing frame 30 of the element 40 is supported by the bosses 51B by point contact, excess stress can be prevented from being applied to the element 40 even when the element 40 is supported in a slanted state.

As mentioned above, the bosses for the fixing support member 50 may be configured as various shapes according to the usage. In descriptions hereinafter, examples using the bosses 51 of the first example are described.

In embodiments described in the specification, since each of the element 40 and the fixing support member 50 functions as a part of the structure of the embodiment, the element 40 may be referred to as a first part, and the fixing support member 50 may be referred to as a second part.

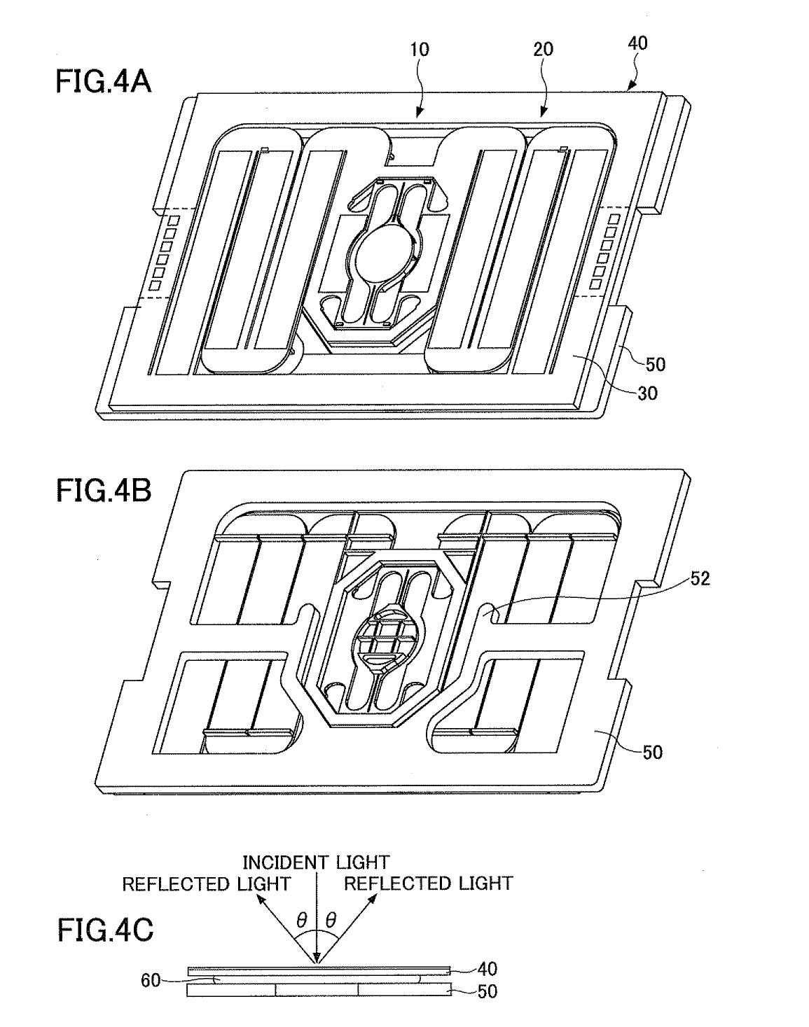

FIGS. 4A-4C are diagrams showing a state in which the element 40 and the fixing support member 50 in the structure of the embodiment 1 are bonded. FIG. 4A is a perspective view of the structure of the embodiment 1 viewed from the side of the element 40 (surface side). FIG. 4B is a perspective view of the structure of the embodiment 1 viewed from the side of the fixing support member 50 (back surface side). FIG. 4C is a side view of the structure of the embodiment 1.

As shown in FIG. 4A, the element 40 is bonded on the fixing support member 50. The element 40 is placed on the fixing support member 50 having large length and width.

As shown in FIG. 4B, the fixing support member 50 is placed in the backside of the structure. The lower stopper 52 for shock resistance covers main parts of the element 40 such that movement of the element 40 to the lower side is restricted.

As shown in FIG. 40, an adhesive 60 exists between the element 40 and the fixing support member 50, so that the element 40 and the fixing support member 50 are bonded by the adhesive 60. As mentioned above, the adhesive 60 may be cured by various curing methods such as ultraviolet curing and the like. Also, a soft adhesive of relatively high consistency after being cured is used so as to absorb thermal deformation of the fixing support member 50. The reason for using the soft adhesive is to prevent the element 40 from being deformed even when the fixing support member 50 is deformed in a high temperature after the adhesive is cured. As mentioned above, the element 40 is composed of semiconductor material such as silicon in many cases. On the other hand, the fixing support member 50 is composed of resin such as acryl and polycarbonate and the like in many cases. Thus, thermal expansion coefficients of the silicon and the resin are different in many cases. If the structure having such a material constitution is heated to a high temperature, deformation of the fixing support member 50 affects the element 40 so that there may be a case in which temperature characteristics of the element 40 deteriorate. In the structure of the present embodiment, in order to prevent the temperature characteristics from being deteriorated, a soft adhesive that can absorb the stress due to deformation of the fixing support member 50 is used for bonding the element 40 and the fixing support member 50. For example, as the adhesive, it is preferable to use a soft adhesive such as an adhesive of after-cured Shore hardness of equal to or less than 200 (JIS-7215).

As mentioned above, by using the soft adhesive, temperature characteristics of the structure in the present embodiment can be improved. FIG. 4C shows an example in which an incident light enters the mirror 11, so that the reflected light scans right and left within a range of 2θ by fluctuation of the mirror 11.

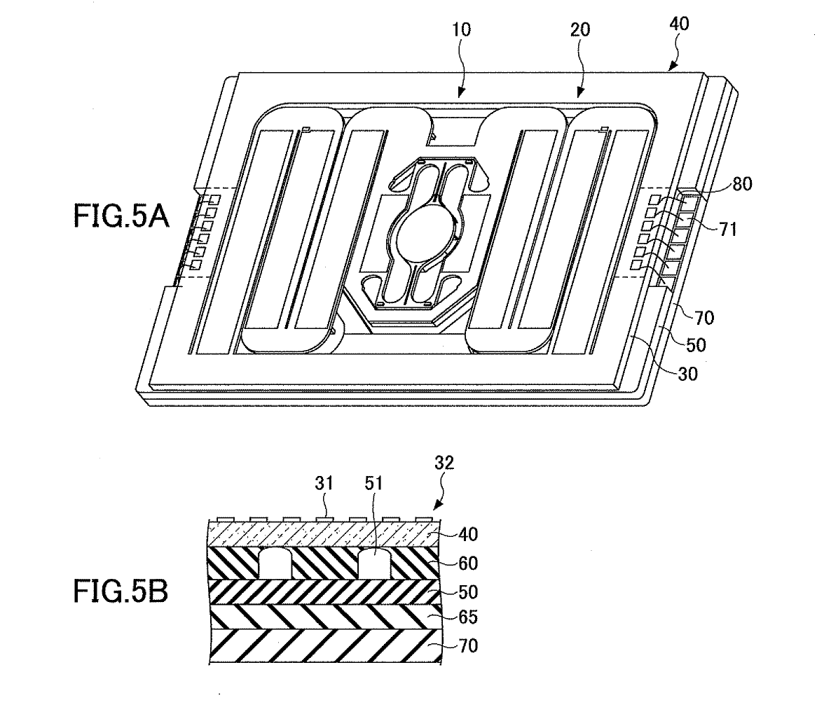

FIGS. 5A and 5B are diagrams showing the structure of the embodiment 1 in which the fixing support member 50 and the element 40 are fixed on a board 70. FIG. 5A is a perspective view showing an example of a configuration in which the fixing support member 50 and the element 40 are fixed on the board 70. As shown in FIG. 5A, the element 40 and the fixing support member 50 that are integrated are fixed on the board 70. As the board 70, a board made of resin such as a printed board may be used, for example. Fixing of the element 40 and the fixing support member 50 to the board 70 may be performed in various ways. For example, the element 40 and the fixing support member 50 may be fixed to the board 70 by adhesive bonding. The adhesive used here may be different from the adhesive 60 used for bonding the element 40 and the fixing support member 50. That is, for bonding the lower surface of the fixing support member 50 to the board 70, various adhesives may be used according to the usage, and there is no limitation such as hardness and the like.

The board 70 includes terminal pads 71 at positions adjacent to the electrode pads 31 of the element 40. After the element 40 and the fixing support member 50 that are integrated are bonded on the board 70, the electrode pads 31 of the element 40 and the terminal pads 71 of the board 70 are wire-bonded so that they are electrically connected. At this time, as the wire bonding, ultrasonic bonding is performed in which a metal wire 80 (wire lead) is pressure-bonded onto the terminal pad 71 and the electrode pad 31 by applying ultrasonic vibration. First, an end of the wire 80 is bonded to the terminal pad 71 by ultrasonic bonding, and next, another end of the wire 80 is bonded to the electrode pad 31 by ultrasonic bonding. If the interstices between the element 40 and the fixing support member 50 are filled only by the soft adhesive like a conventional structure, the ultrasonic vibration is absorbed by the adhesive so that the ultrasonic vibration cannot be transmitted to the electrode pad 31 sufficiently when the wire 80 is bonded to the electrode pad 31 of the element using the ultrasonic bonding. However, in the structure of the present embodiment, since there are bosses 51 between the element 40 and the fixing support member 50, the ultrasonic vibrations are prevented from being absorbed by the adhesive 60, so that the ultrasonic vibrations can be sufficiently transmitted to the electrode pad 31.

FIG. 5B is a diagram showing an example of a sectional configuration of the structure around the bosses 51. As shown in FIG. 5B, the adhesive 65, the fixing support member 50, the bosses 51, the adhesive 60 and the element 40 are laminated on the semiconductor board 70 in this order from the bottom. The electrode pads 31 are formed on the surface of the element 40 in the electrode pad forming area 32. In this configuration, when ultrasonic bonding is performed on each electrode pad 31, the ultrasonic vibrations applied to the electrode pad 31 are not transmitted through the adhesive 60 so as to directly vibrate the element 40 since the element 40 is fixed by the bosses 51. That is, although the adhesive 60 becomes soft due to ultrasonic vibrations when performing ultrasonic bonding, the ultrasonic vibrations can be transmitted to the element 40 so as to vibrate the element 40 since the bosses 51 fixes the element 40. Accordingly, wire bonding on the electrode pads 31 can be performed without problem, so that the electrode pads 31 and the terminal pads 71 can be electrically connected by wires 80.

It is possible to perform wire bonding using a hard adhesive without providing the bosses 51. However, in the case where a hard adhesive 60 is used, when the fixing support member 50 is deformed due to high temperature, the deformation is transmitted to the element 40 through the adhesive 60. Thus, temperature characteristics of the structure are deteriorated. Thus, like the structure of the present embodiment, by using the soft adhesive 60 that can absorb stress and by providing bosses 51 at the bonding surface of the fixing support member 50, ultrasonic bonding can be properly performed while realizing good temperature characteristics.

As shown in FIG. 5B, an adhesive 65 exists also between the board 70 and the fixing support member 50. As mentioned above, any adhesive may be used as the adhesive 65. The reason is that the adhesive 65 is not involved in the ultrasonic bonding to the terminal pads 71 on the board 70, and that it is difficult to consider that the ultrasonic vibrations in ultrasonic bonding of the electrode pads 31 reach the adhesive 65 to soften the adhesive 65 and the vibrations are transmitted.

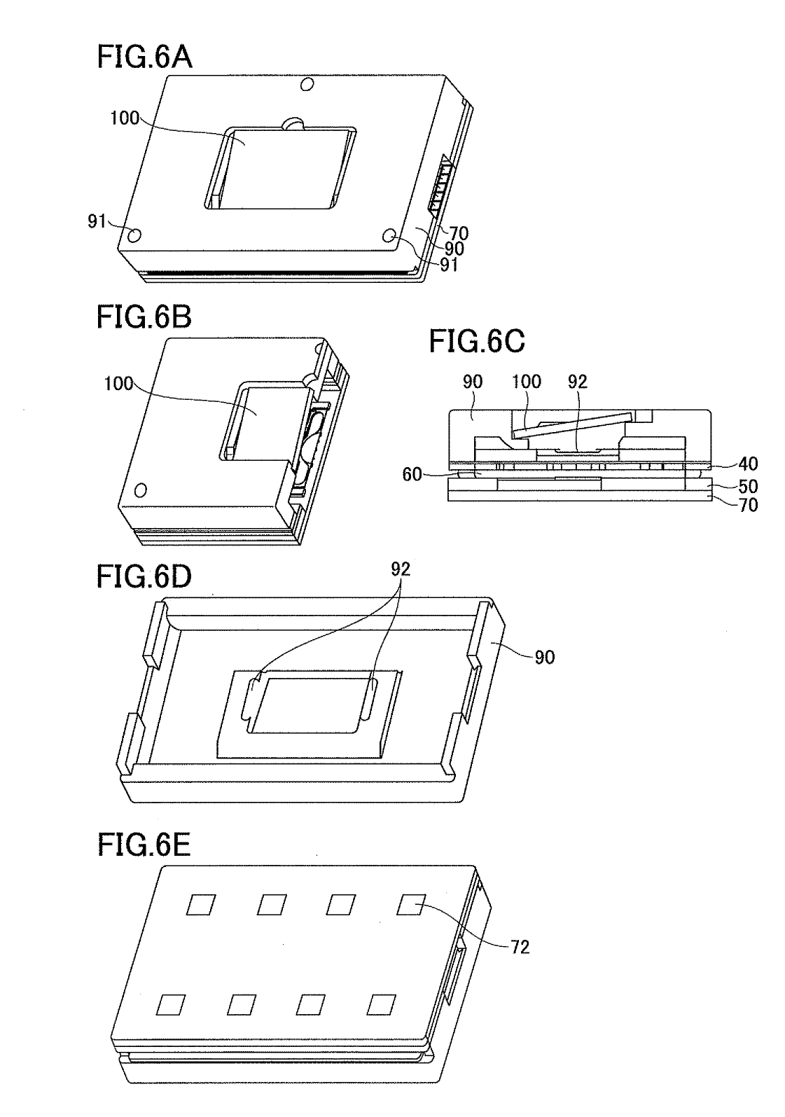

FIGS. 6A-6E are diagrams showing a packaging finished state of the structure of the embodiment 1. FIG. 6A is a diagram showing a packaging finished state of the structure of the embodiment 1. In FIG. 6A, a state is shown in which a cover 90 covers the board 70 from the upper surface. Accordingly, the fixing support member 50 and the element 40 that are fixed on the board 70 are packaged by being covered by the cover 90. The cover 90 includes positioning bosses 91 and a transparent plate on the upper surface of the cover 90. The positioning bosses are fitting units configured to position the structure of the present embodiment configured as an optical scanning apparatus when attaching the structure to a projector unit and the like. Also, the transparent plate 100 is provided in a position where the mirror 11 of the element 40 is placed. For example, the transparent plate 100 may be configured to be a transparent plate with antireflective films in which antireflective films are provided in both sides.

FIG. 6B is a sectional side perspective view of the packaged state of the structure of the embodiment 1. FIG. 6C is a side section view of the packaged state of the structure of the embodiment 1. FIG. 6C shows a configuration in which the board 70, the fixing support member 50, the adhesive 60, the element 40 and the cover 90 are laminated in this order from the bottom. The cover 90 includes an upper stopper 92 for shock resistance above the element 40. Thus, the structure is configured such that the element 40 is prevented from being broken even when an impact is applied due to falling and the like. Also, the transparent plate 100 is provided on the center surface of the cover 90 so that the mirror 11 is protected.

FIG. 6D is a perspective view showing a configuration of the backside of the cover 90. As shown in FIG. 6D, a configuration of the upper stopper 92 for shock resistance is shown. Accordingly, the cover 90 includes the upper stopper 92 for shock resistance, so that the inside element 40 is prevented from being shocked when the element 40 is packaged.

FIG. 6E is a diagram showing the backside of the board 70. As shown in FIG. 6E, electrodes 72 are provided on the backside of the board 70. Each electrode 72 is electrically connected to the terminal pad 71 on the surface side so that power can be supplied to the inside element 40 from the electrode 72 via the terminal pad 71.

Since the structure of the embodiment 1 can be formed as a micro structure using the MEMS technique, the package of the structure of the embodiment 1 may be configured with a size level of height 7.0 mm×width 11.5 mm×depth 2.4 mm.

According to the structure of the embodiment 1, by performing only laminating processes that can be performed easily, a highly accurate structure can be obtained in which temperature characteristics are good and ultrasonic bonding can be properly performed.

### Embodiment 2

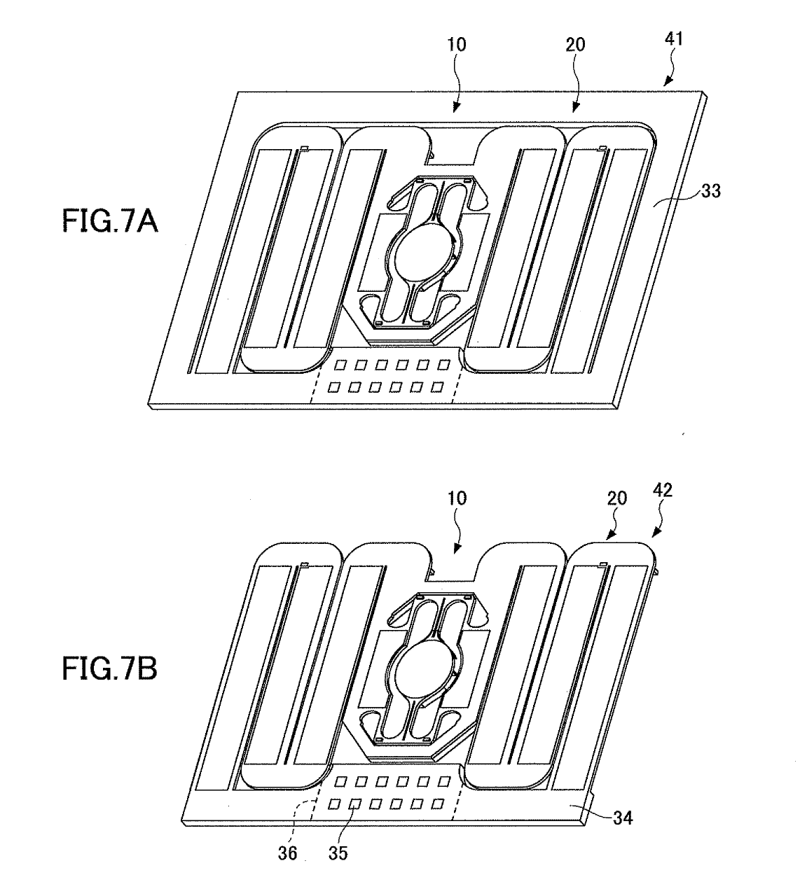

FIGS. 7A and 7B are diagrams for explaining a configuration of an element in a structure of the embodiment 2. Similarly to the embodiment 1, the structure of the embodiment 2 is described as a configuration of an optical scanning apparatus. Also, components the same as those in the embodiment 1 are assigned the same reference symbols and the descriptions are not given.

FIG. 7A is a perspective view showing a configuration of the element 41. As shown in FIG. 7A, the element 41 of the embodiment 2 is similar to the element 40 of the structure of the embodiment 1 in that the horizontal driving part 10 and the vertical driving part 20 are provided and that the fixing frame 33 surrounds the circumference.

FIG. 7B is a perspective view showing an example of a configuration of an element 42 in a structure of the embodiment 2. In the element 42 shown in FIG. 7B, the right and the left sides and the back side of the fixing frame 33 are removed from the element 41 shown in FIG. 7A, so that only a fixing piece 34 that is one side of the fixing frame 33 remains. Also, the electrode pads 35 are provided in an electrode pad forming area 36 around the center of the fixing piece 34. In the structure of the embodiment 1, the electrode pads are provided in both sides of the fixing frame 30 on halves. On the other hand, in the structure of the embodiment 2, the electrode pads 35 are provided in the electrode pad forming area 36 that is one place located near the center. Thus, the space is doubled and the area 36 is a plane having a convex shape protruding to the inside.

Accordingly, in the structure of the embodiment 2, the part supporting the element 42 is limited to a minimum that is only the fixing piece 34 so that the element 42 of a small area can be formed. Since the element 42 is formed by a semiconductor, it becomes possible to increase the number of elements 42 obtained from one semiconductor wafer, so that the structure can be formed at low cost. In the embodiment 2, an example of a structure of a low priced/small-sized element package is described.

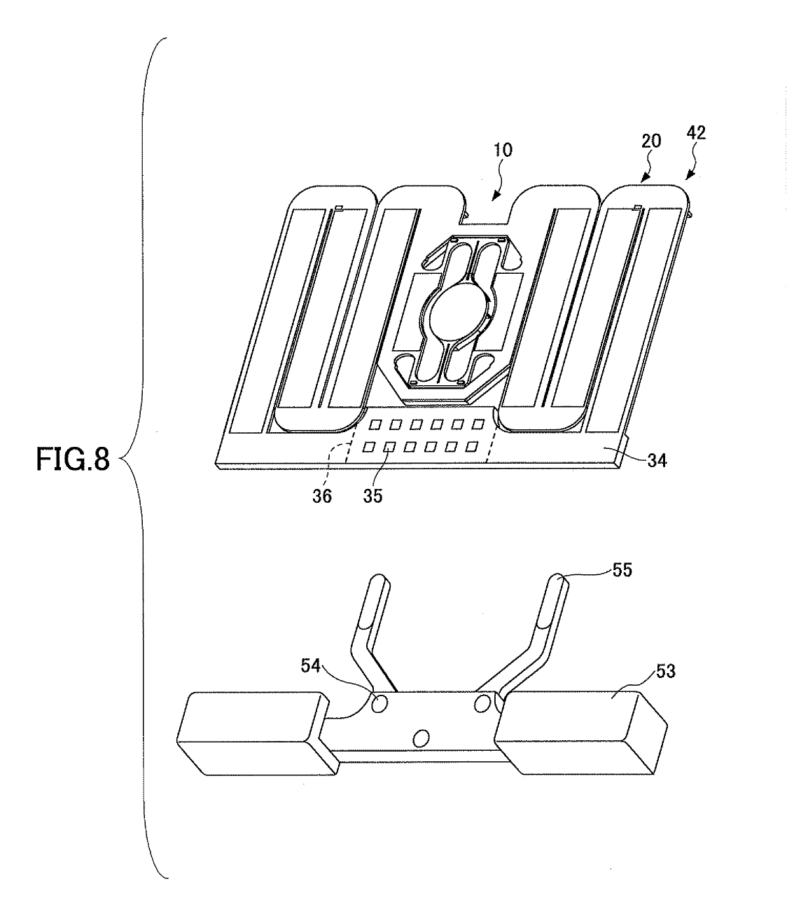

FIG. 8 is a diagram showing the fixing support member 53 of the structure of the embodiment 2 with the element 42. In FIG. 8, the fixing support member 53 has a shape for supporting only one side which corresponds to the fixing piece 34. Also, the fixing support member 53 includes three bosses 54 at positions corresponding to the electrode pads 35 provided in the electrode pad forming area 36 of the fixing piece 34 of the element 42. Each boss 54 is provided at a position that overlaps an electrode pad 35 when the fixing support member 53 and the element 42 are bonded. Accordingly, similarly to the embodiment 1, ultrasonic bonding to the electrode pads 35 can be performed with reliability in the later bonding process.

Also, different from the embodiment 1, three bosses 54 are provided. In the structure of the embodiment 2, since the electrode pads 35 are aggregated in one place so that the electrode pad forming area 36 is narrowed, the number of the bosses 54 are reduced to a minimum number, that is, three. Various shapes may be adopted for the bosses 54 as described in FIGS. 3A-3C.

When the element 42 and the fixing support member 53 are bonded with the ultraviolet curing adhesive, the fixing support member 53 is formed by a transparent resin molding part such as the acryl resin or polycarbonate resin or the like, which is similar to the structure of the embodiment 1.

The fixing support member 53 includes a lower stopper 55 for shock resistance, so that the element 42 is protected even when the structure receives an impact due to falling and the like, which is similar to the structure of the embodiment 1.

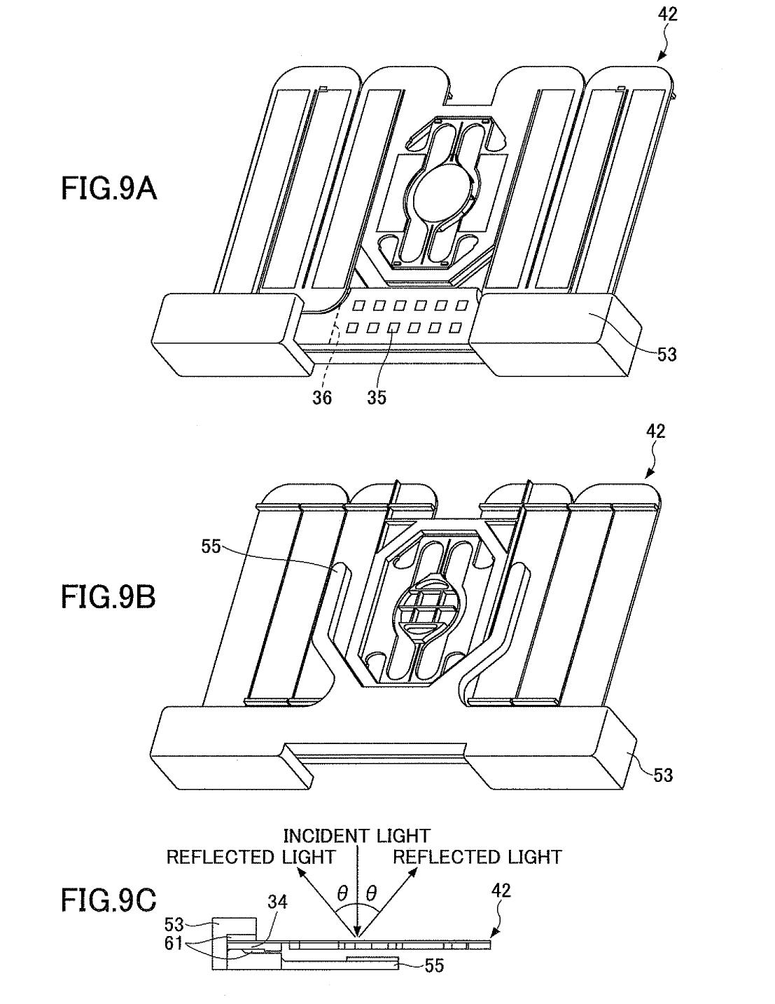

FIGS. 9A-9C are diagrams showing the structure of the embodiment 2 in which the element 42 and the fixing support member 53 are bonded so that they are integrated. FIG. 9A is a perspective view of the structure of the embodiment 2 in which the element 42 and the fixing support member 53 are bonded so that they are integrated, viewed from the side of the element 42 (the side of the front surface). As shown in FIG. 9A, the element 42 is bonded to the fixing support member 53 such that the fixing piece 34 is inserted into the fixing support member 53 toward the back end of the fixing support member 53. The bosses 54 exist on the bonding surface of the fixing support member 53 overlapping the electrode pad forming area 36.

FIG. 9B is a perspective view of the structure of the embodiment 2 in which the element 42 and the fixing support member 53 are bonded so that they are integrated, viewed from the side of the fixing support member 53 (the side of the back surface). As shown in FIG. 9B, one side of the element 42 is held on the front side by the fixing support member 53 like a cantilever. Also, FIG. 9B shows that the backside is guarded by the lower stopper 55 for shock resistance.

FIG. 9C is a side view of the structure of the embodiment 2 in which the element 42 and the fixing support member 53 are bonded so that they are integrated. As shown in FIG. 9C, the base portion of the fixing support member 53 and the portion of the fixing piece 34 of the element 42 are bonded by an adhesive 61. There is the lower stopper 55 for shock resistance at the bottom, and the element 42 is bonded on the upper surface of the base portion of the fixing support member 53 by the adhesive 61. Further, the fixing support member 53 is configured to sandwich the element 42 from upper and lower sides. Thus, the undersurface of the fixing support member 53 existing on the top surface of the element 43 is bonded and fixed to the top surface of the element 43 by the adhesive 61. Accordingly, in the structure of the embodiment 2, the element 42 may be bonded to the fixing support member 53 by the adhesive 61 such that the fixing support member 53 sandwiches the element 42 from upper and lower sides.

Similarly to the embodiment 1, an adhesive having a consistency that can absorb the stress due to deformation of the fixing support member 53 is used as the adhesive 61. For example, as the adhesive, a soft adhesive 61 such as an adhesive of after-cured Shore hardness of equal to or less than 200 (JIS-K-7215) may be used similarly to the embodiment 1. By adopting the configuration in which the element 42 and the fixing support member 53 are bonded with the soft adhesive 61, temperature characteristics of the structure of the embodiment 2 can be improved.

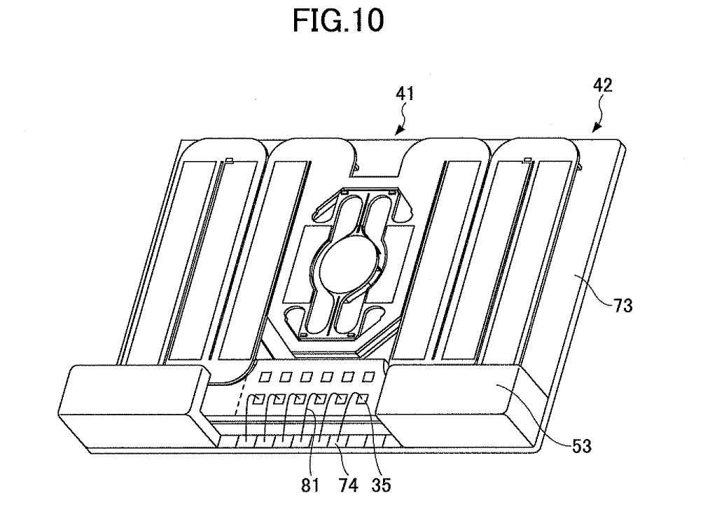

FIG. 10 is a perspective view showing a structure of the embodiment 2 in which the fixing support member 53 and the element 42 are fixed on a board 73. As shown in FIG. 10, the fixing support member 53 and the element 42 are bonded on the board 73, and the electrode pads 35 of the element 42 are connected to the terminal pads 74 of the board 73 by wires 81. Like the embodiment 1, wire bonding using each wire 81 may be performed by the ultrasonic bonding. The ultrasonic bonding is performed by pressure-bonding the wire 81 to the terminal pad 74 and the electrode pad 35 while applying ultrasonic vibrations. Ultrasonic bonding to the electrode pad 35 can be performed without dissipating (escaping) the ultrasonic vibrations in the adhesive 61 due to the bosses 54 provided on the bonding surface of the fixing support member 53 bonded to the element 42, so that the parts can be properly bonded by the ultrasonic bonding.

Also, in the structure of the embodiment 2, the terminal pads 74 in the side of the board 73 are adjacent to the electrode pads 35 in the side of the element 42 so that wire bonding can be performed with a minimum length of wires 81. Accordingly, also in the structure of the embodiment 2 configured as a low-priced/small sized element package, the ultrasonic bonding can be performed properly similarly to the structure of the embodiment 1.

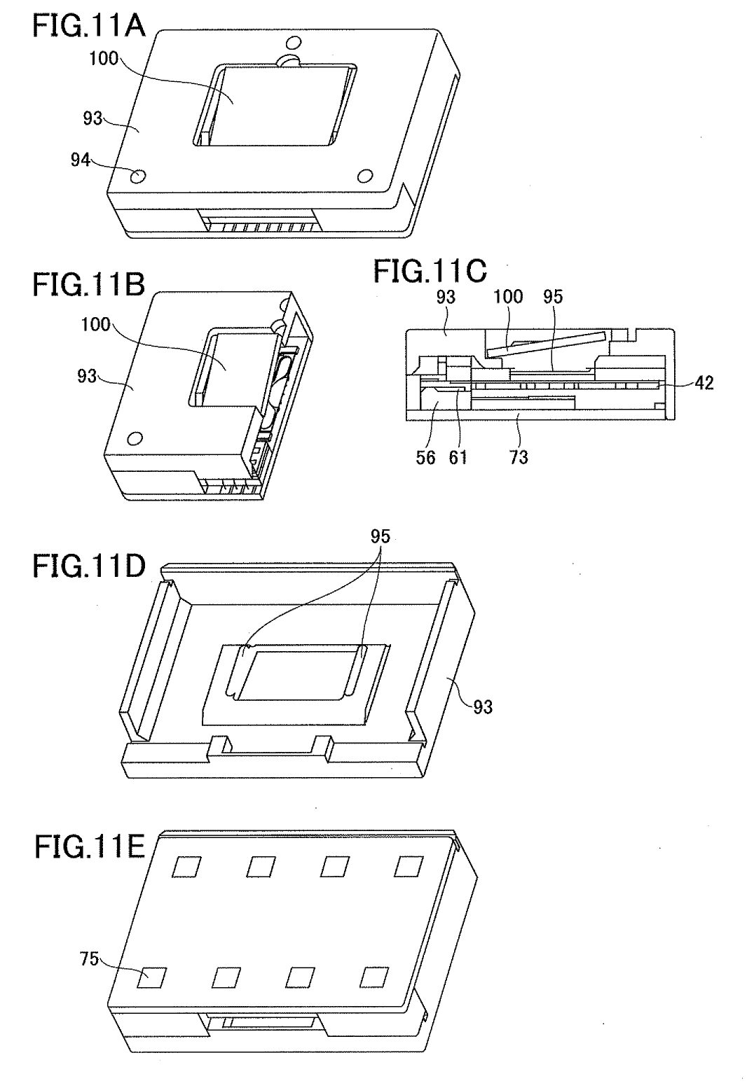

FIGS. 11A-11E are diagrams showing a packaging finished state of the structure of the embodiment 2. FIG. 11A is a perspective view showing a whole configuration of a packaging finished state of the structure of the embodiment 2. As shown in FIG. 11A, also in the structure of the embodiment 2, a cover 93 covers the element 42, the fixing support member 53 and the board 73. The cover 93 includes positioning bosses 94 on the surface for positioning when attaching to a projector unit, and the transparent plate 100 is provided in a center part, which configuration is similar to the structure of the embodiment 1.

FIG. 11B is a perspective view showing a sectional configuration of the structure of the embodiment 2 after packaging is finished. FIG. 11C is a side section view showing a sectional configuration of the structure of the embodiment 2 after packaging is finished. As shown in FIG. 11C, the board 73, the fixing support member 53, the adhesive 61, the element 42 and the cover 93 are laminated in this order from the bottom. The cover 93 includes an upper stopper 95 for shock resistance above the element 42 inside the cover 93 so as to protect the element 42 from the upper side. Also, the transparent plate 100 is provided on the center part of the cover 93 similarly to the embodiment 1.

FIG. 11D is a diagram showing a configuration of the backside of the cover 93, which is different from the embodiment 1 in that the cover 93 covers only three sides. Similarly to the structure of the embodiment 1, the cover 93 is provided with the upper stopper 95 for shock resistance in a portion where the element 42 is placed.

FIG. 11E is a diagram showing the backside of the structure of the embodiment 2 after packaging is finished. As shown in FIG. 11E, similarly to the structure of the embodiment 1, electrodes 75 are provided on the backside of the board 73, which enables conduction of electricity with the element 42.

In the structure of the embodiment 2, the element 41 shown in FIG. 7A is configured with a size the same as the size of the element 40 of the structure of the embodiment 1. Then, after that, processing is performed, so that a package of the structure of the embodiment 2 can be configured with a size of height 7.0 mm×width 10.0 mm×depth 2.4 mm. Accordingly, the width can be reduced by 1.5 mm compared to the package of the structure of the embodiment 1.

According to the embodiment 2, the small-sized structure can be realized with low cost, temperature characteristics can be improved, and wire bonding can be properly performed by ultrasonic bonding.

### Embodiment 3

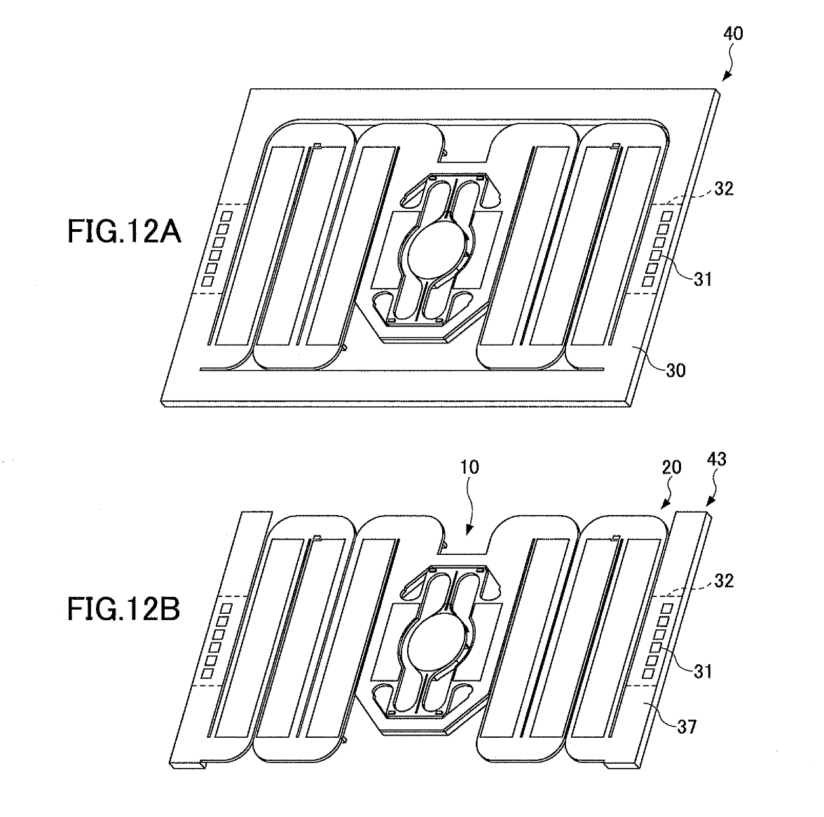

FIGS. 12A and 12B are diagrams for explaining a configuration of an element of the structure of the embodiment 3. In the embodiment 3, an example of a structure of a short-height package is described. Also, components the same as those in the embodiment 1 are assigned the same reference symbols and the descriptions are not given. FIG. 12A is a diagram showing a configuration similar to the element 40 of the structure of the embodiment 1. FIG. 12B is a diagram showing an example of a configuration of the element 43 of the structure of the embodiment 3.

The element 43 of the structure of the embodiment 3 shown in FIG. 12B is obtained, from the element 40 shown in FIG. 12A by removing the front side and the back side of the fixing frame 30. The element 43 of the structure of the embodiment 3 is configured such that fixing members 37 are provided only on two sides of the vertical driving part 20. The electrode pads 31 are provided in each of the electrode pad forming areas 32 on the center portion of the right and the left fixing members 37.

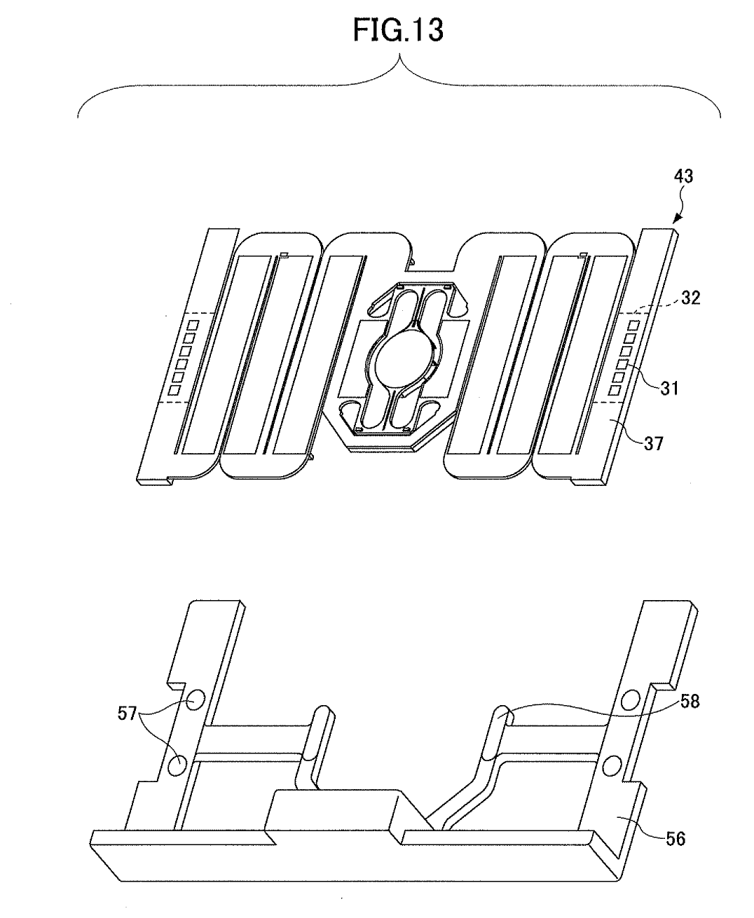

FIG. 13 is a diagram showing the fixing support member 56 of the structure of the embodiment 2 with the element 43. The fixing support member 56 is configured to surround three sides without a part corresponding to the rear side. The fixing support member 56 includes bosses 57 on the upper surface such that the bosses 57 correspond to the electrode pads 31 of the element 43. Similarly to the embodiment 1, two bosses 57 are provided in each of the two sides. A lower stopper 58 for shock resistance is provided near the center potion of the fixing support member 56. The bosses 57 can be configured in various shapes as described with reference to FIGS. 3A-3C.

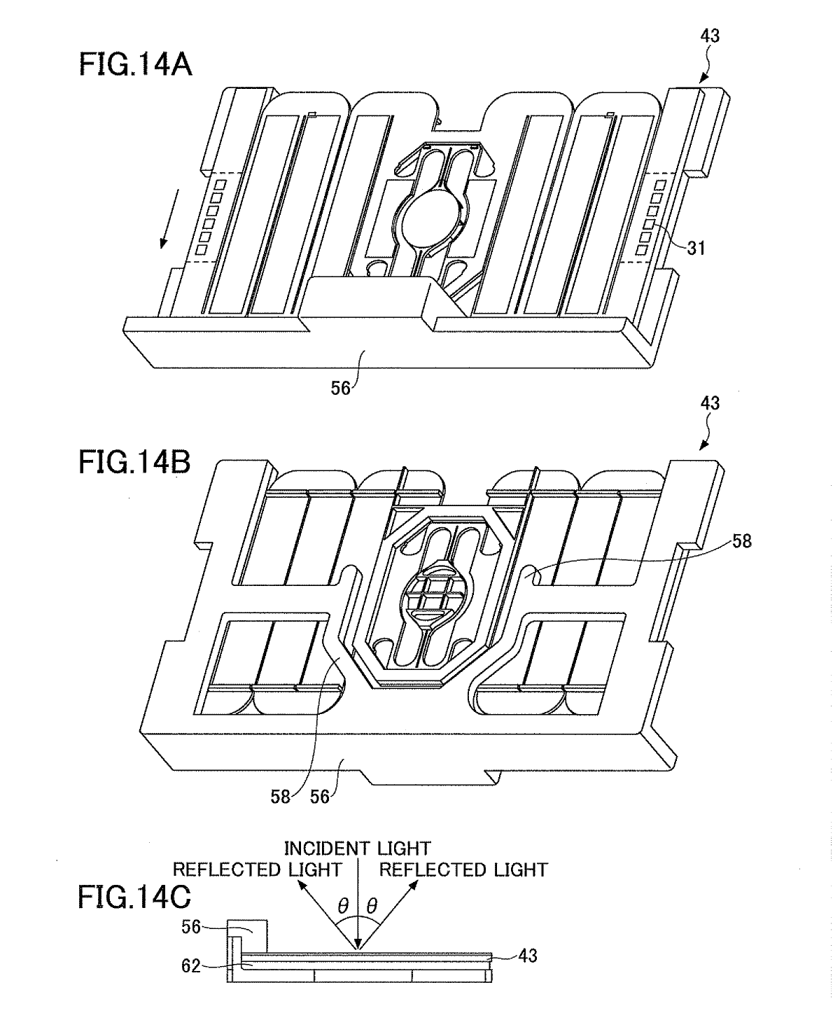

FIGS. 14A-14C are diagrams showing the structure of the embodiment 2 in which the element 43 and the fixing support member 56 are bonded. FIG. 14A is a perspective view of the structure of the embodiment 3 in which the element 43 and the fixing support member 56 are bonded, viewed from the side of the element 43 (the side of the front surface). As shown in FIG. 14A, the element 43 is bonded and fixed to the fixing support member 56 such that the element 43 is inserted into the fixing support member 56 as far as it touches the back end. The element 43 is placed on the bonding surface of the fixing support member 56, and is bonded at a position in which the bosses 57 overlap electrode pads 31.

FIG. 14B is a perspective view of the structure of the embodiment 3 in which the element 43 and the fixing support member 56 are bonded, viewed from the side of the fixing support member 56 (the backside). As shown in FIG. 14B, the backside of the element 43 is covered by the lower stopper 58 for shock resistance. Therefore, even though the element 43 receives an impact due to falling and the like, the lower stopper 58 for shock resistance functions as a cushion.

FIG. 14C is a side view of the structure of the embodiment 3 in which the element 43 and the fixing support member 56 are bonded. As shown in FIG. 14C, the fixing support member 56 and the element 42 are bonded by an adhesive 62. The fixing support member 56 is configured to cover an end portion of the element 43 so as to sandwich the end portion from upper and lower sides. As described in the embodiment 1, an adhesive having softness that can absorb the stress due to deformation of the fixing support member 56 in high temperature is used as the adhesive 61. For example, as the adhesive, a soft adhesive such as an adhesive of after-cured Shore hardness of equal to or less than 200 (JIS-K-7215) may be used similarly to the embodiment 1. Accordingly, temperature characteristics of the structure can be improved.

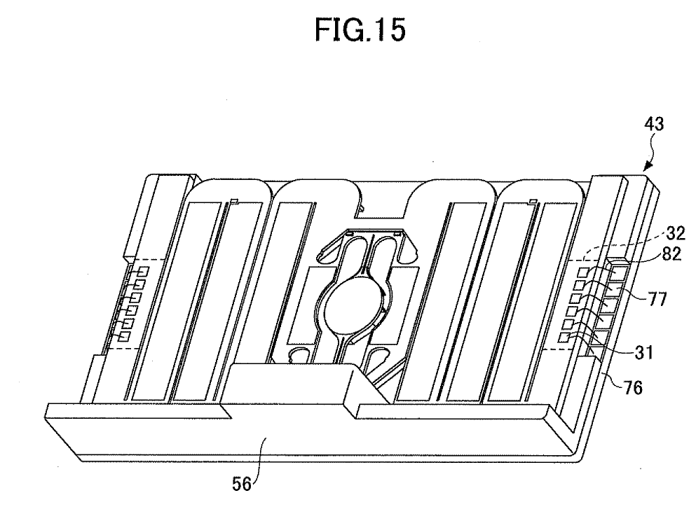

FIG. 15 is a diagram showing the structure of the embodiment 3 in which the fixing support member 56 and the element 43 are fixed on a board. As shown in FIG. 15, a part in which the element 43 is bonded on the fixing support member 56 with an adhesive 62 is placed on the board 76 and fixed by bonding. As the adhesive used in this case, any adhesive may be used. After the fixing support member 56 and the element 43 are bonded on the board 76, the terminal pads 77 provided on the board 76 and the electrode pads 31 of the element 43 are connected using wires 82 by ultrasonic bonding. As described in the embodiment 1, since the lower surface of the electrode pads 31 is supported by the bosses 57, wire bonding can be performed properly without dissipation of ultrasonic vibrations via the adhesive 61.

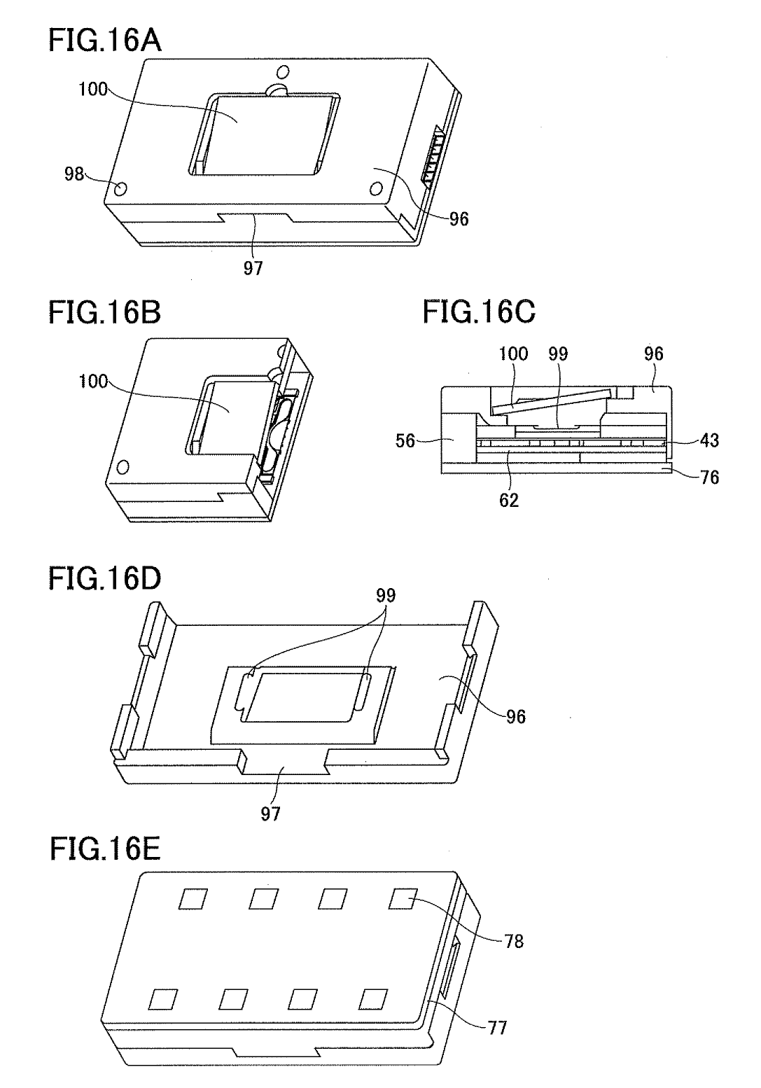

FIGS. 16A-16E are diagrams showing the structure of the embodiment 3 after packaging is finished. FIG. 16A is a perspective view showing the whole structure of the embodiment 3 after packaging is finished. As shown in FIG. 16A, the fixing support member 56 and the element 43 bonded on the board 77 are covered by the cover 96. The cover 96 includes a concave shape portion at the center portion, and is configured to fit with the convex portion at the front center part of the fixing support member 56. The configuration is different from the covers 90 and 93 of the structure of the embodiment 1 and the embodiment 2. According to the fitting structure, the structure can be configured to be low in height.

Similarly to the structure of the embodiments 1 and 2, positioning bosses 98 are provided on the upper surface of the cover 96 for attaching to a projector unit, and the transparent plate 100 with both-sided antireflective films is provided at the center portion of the cover 96.

FIG. 16B is a perspective view showing a sectional configuration of the structure of the embodiment 3 after packaging is finished. FIG. 16C is a side section view showing a sectional configuration of the structure of the embodiment 3 after packaging is finished. As shown in FIG. 16C, the board 76, the fixing support member 56, the adhesive 62, the element 43 and the cover 96 are laminated in this order from the bottom. The cover 93 includes an upper stopper 99 for shock resistance above the element 42 inside the cover 93 so as to protect the element 43 even though the structure receives an impact due to falling and the like. Also, the transparent plate 100 is provided on the center surface of the cover 96. Light is irradiated onto the mirror 11 of the element 43 via the transparent plate 100.

FIG. 16D is a diagram showing a configuration of the backside of the cover 96. The side of the front portion of the cover 96 is provided with a concave portion with which the fixing support member 56 fits, so that the height is reduced. Similarly to the covers 90 and 93 of the embodiments 1 and 2, the cover 96 is provided with the upper stopper 99 for shock resistance.

FIG. 16E is a diagram showing an example of a configuration of the backside of the structure of the embodiment 3 after packaging is finished. The board 77 is placed on the backside of the structure, and electrodes 78 are provided on the backside of the board 77. Power is supplied to the element 43 via the electrodes 78 to drive the structure, which is similar to the structure of the embodiments 1 and 2.

When the size of the element shown in FIG. 12A is the same as the size of the embodiment 1, the package of the structure of the embodiment 3 can be configured with a size of height 6.0 mm×width 11.5 mm×depth 2.4 mm. Accordingly, the height can be reduced by 1.0 mm.

As mentioned above, according to the structure of the embodiment 3, a package of a low height can be configured in which temperature characteristics are high, and ultrasonic bonding can be properly performed.

### Embodiment 4

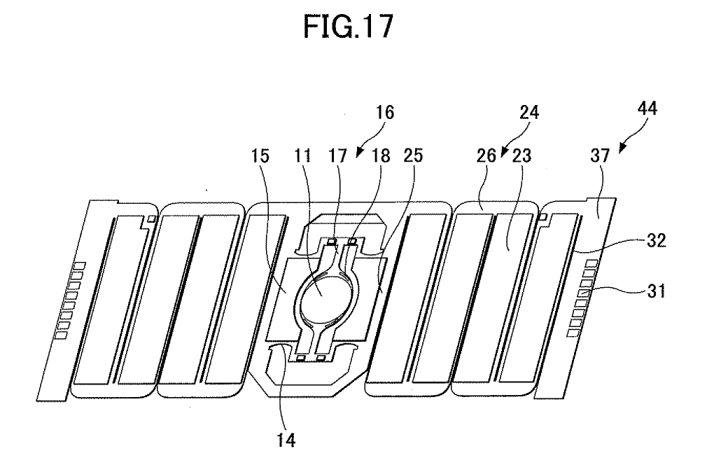

FIG. 17 is a diagram showing an example of the structure of the embodiment 4. In FIG. 17, components the same as those in the embodiments 1-3 are assigned the same reference symbols and the descriptions are not given.

As shown in FIG. 17, the element 44 of the structure of the embodiment 4 includes a horizontal driving part 16, a vertical driving part 24 and a fixing member 37.

Similarly to the elements 40-43 of the structure of the embodiments 1-3, the horizontal driving part 16 includes the mirror 11, the twisting beams 17, the slits 18, the horizontal driving beams 14 and the driving sources 15. But, the element 44 is different from the elements 40-43 of the structure of the embodiments 1-3 in that the slits 18 are not formed in the elongate portion of the twisting beams 17, but the slits 18 are formed around the mirror 11. The slits 18 soften the stress due to twisting in a portion near the mirror in the twisting beams 17, so as to prevent the portion near the mirror in the twisting beams from being broken. As mentioned above, the horizontal driving part 16 may be configured in various ways. Since the mirror 11, the horizontal driving beams 14 and the driving sources 15 are the same as those of the elements 40-43 of the structure of the embodiments 1-3, the same reference symbols are assigned, and the descriptions are not given.

The vertical driving part 24 is different from corresponding one of the elements 40-43 of the structure of the embodiments 1-3 in that four straight parts of the vertical driving beams 26 are provided in one side instead of three. Also, the size of the movable frame 25 is increased, and the movable frame 25 is configured to surround the horizontal driving part 16 with an interval, which is also different from the embodiments 1-3. Similarly to the elements 40-43 of the structure of the embodiments 1-3, a driving source 23 is provided on the surface of each straight part of the vertical driving beams 26.

As shown in FIG. 17, since the vertical driving beams 26 are configured to include four pieces of straight parts in one side, the area of the vertical driving beams 26 increases a little. But, the number of driving beams of different phases can be made always the same between two sides of the mirror 11. Thus, the magnitude of the angle of fluctuation in the vertical direction can be made the same between slanting to the front side and slanting to the rear side. Accordingly, also the vertical driving part 24 can be configured in various ways according to the usage.

Compared to the fixing member 37 of the element 43 of the structure of the embodiment 3, although the fixing member 37 of this embodiment is connected to the vertical driving beam 26 at opposite positions, the shape and the configuration of the fixing member 37 of the element 43 of the structure of the embodiment 4 are the same as those of the embodiment 3, the same reference symbols are assigned and the description is not given. Also, the electrode pads 31 and the electrode pad forming areas 32 are similar to those of the structure of the elements 40-43 of the embodiments 1-3. Thus, the same reference symbols are assigned and the corresponding description is not given.

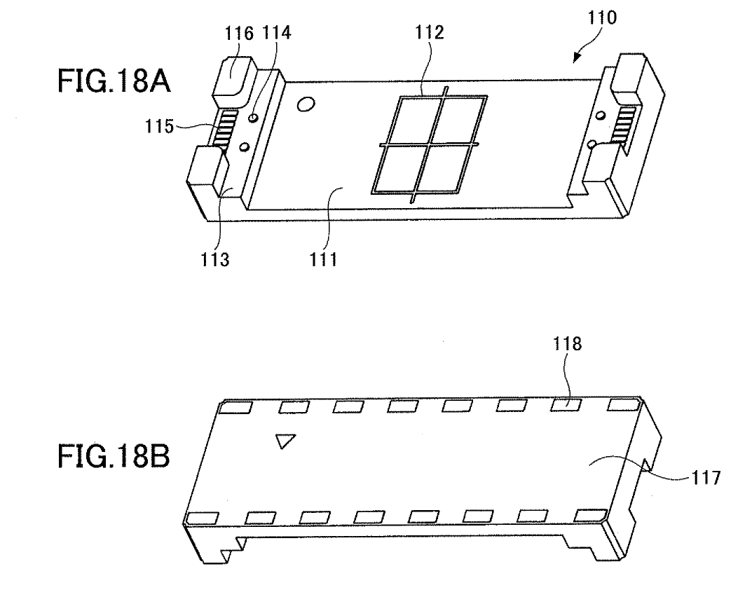

FIGS. 18A and 18B are diagrams showing an example of a package of the structure of the embodiment 4. FIG. 18A is a top perspective view of the package of the structure of the embodiment 4, and FIG. 18B is a bottom perspective view of the package of the structure of the embodiment 4.

As shown in FIG. 18A, the package 110 includes a bottom part 111, a positioning mark 112, element fixing parts 113, bonding members 114, terminal pads 15 and attaching parts 116. The package 110 is an accommodation member for packaging the element 44 shown in FIG. 17, and the element 44 is attached and fixed to the upper surface of the package 110. As material for the package 110, various materials can be used according to usage. For example, ceramics may be used.

The bottom part 111 is a part formed as a concave shape sagging with respect to the element fixing parts 113 for keeping a space in the depth direction where the mirror 11 fluctuates. Thus, the element 44 is held in the package 110 without contacting with the bottom part 111. The bottom part 111 may be formed as a plane in an example of shown in FIG. 18A. Also, in the case where a lower stopper for shock resistance is provided, a groove may be formed in the bottom part 111 by further digging the center part or the bottom part 111 may be formed to be raised like a convex shape.

The positioning mark 112 is a mark used as a reference for positioning the element 44 such that the mirror 11 is placed at the center when the structure is packaged by attaching the element 44. That is, the element 44 is attached such that the center of the mirror 11 agrees with the cross of the center of the positioning mark 12.

Each element fixing part 113 is a part on which the element 44 is placed and fixed. The element fixing part 113 forms a horizontal plane elevated with respect to the bottom part 111. The fixing member 37 of the element 44 is placed on the element fixing part 113, and the element 44 is bonded or connected using an adhesive and the like.

The element fixing part 113 includes bonding members 114 and terminal pads 115. The bonding members 114 are members provided on the element fixing surface that is a bonding surface. Each bonding member 114 may be a boss of a protruded shape like the bosses 51, 54 and 57 of the structure of the embodiments 1-3, or may be an elevated member, rather than a protruded member, that is elevated a little with respect to the surrounding part. Also, the bonding member 114 may be a projection, a hollow, or a groove or the like that may be used as positioning for bonding. Also, the bonding member 114 may be a member that is provided on the bonding surface used for bonding or used being related to bonding. In FIG. 18A, two boss-like bonding members 114 are provided at the center part in each of the element fixing parts 113. Accordingly, similarly to the embodiments 1-3, ultrasonic bonding can be properly performed. Although the number and the position of the bonding members 114 may be variously changed according to the usage, the bonding members 114 are provided at positions where the electrode pads 31 of the element 44 are placed for the ultrasonic bonding. As a result, the bonding members 114 are provided at positions adjacent to the terminal pads 115.

Each terminal pad 115 is a terminal for electrically connecting with the electrode pad 31 of the element 44. Accordingly, it becomes possible to electrically connect to an external unit.

Each attaching part 116 is a joint part for attaching the package 110 that accommodates and holds the element 44 in a predetermined position of a cabinet and the like. For example, in the case when the package 110 is attached to a plate-like part or a wall-like part of a cabinet, the attaching part 116 is connected to a predetermined attaching position of the cabinet, so that the package 110 is attached while maintaining a gap of the height of the attaching part 116 between the cabinet and the element 44. Accordingly, a space can be kept in a height direction in which the mirror 11 fluctuates, and the element 44 can be properly fixed and supported.

Also, two attaching parts 116 are provided outside of the terminal pads 115 in the shorter direction of the package 110 in each side of the longitudinal direction, so that the attaching parts 116 do not obstruct placement and electrical connection of the terminal pads 115. Accordingly, the electrode pads 31 and the terminal pads 115 can be electrically connected at the center portion. By providing the attaching parts 116, the package can be properly attached to a cabinet and the like while maintaining a configuration of proper electrical connections.

Two attaching parts 116 are provided in each side of the longitudinal direction. Therefore, four attaching parts 116 are provided as a whole. In the case when the package 110 is attached to a predetermined position of a cabinet, it is enough to provide three attaching parts 116 at the minimum. But, in the case when the terminal pads 115 are provided at the center part in the shorter direction in each side of the longer direction, the attaching parts 116 are provided outside the terminal pads 115 (four attaching parts 116 in total), so that the attaching parts 116 serve both of proper electrical connection and attachment to the cabinet.

Also, two attaching parts 116 in total may be provided where each attaching part 116 has a shape like a rail extending along each shorter side. However, in this case, the terminal pads 115 cannot be provided on the edge part. Thus, in the present embodiment, the package 110 is configured to include two attaching parts 116 outside the terminal pads 115 in each of the two sides so that four attaching parts 116 are provided as a whole.

As mentioned above, the package 110 is configured to include the element fixing part 113 as an intermediate stage, and include the bottom part 111 that is lower than the element fixing part 113, and include the attaching part 116 that is higher than the element fixing part 113. Thus, a space can be kept above and under the mirror 11 where the mirror 11 can fluctuate. That is, the element 44 can be packaged and can be attached to a cabinet in a state where the element 44 can properly operate.

FIG. 18B shows the backside of the package 110. The backside 117 of the package 110 is provided with plural external connection terminals 118, so that connection to an external unit is available. The external connection terminals 118 are electrically connected to the terminal pads 115 on the upper surface side so that the external connection terminals 118 can be electrically connected to the element 44.

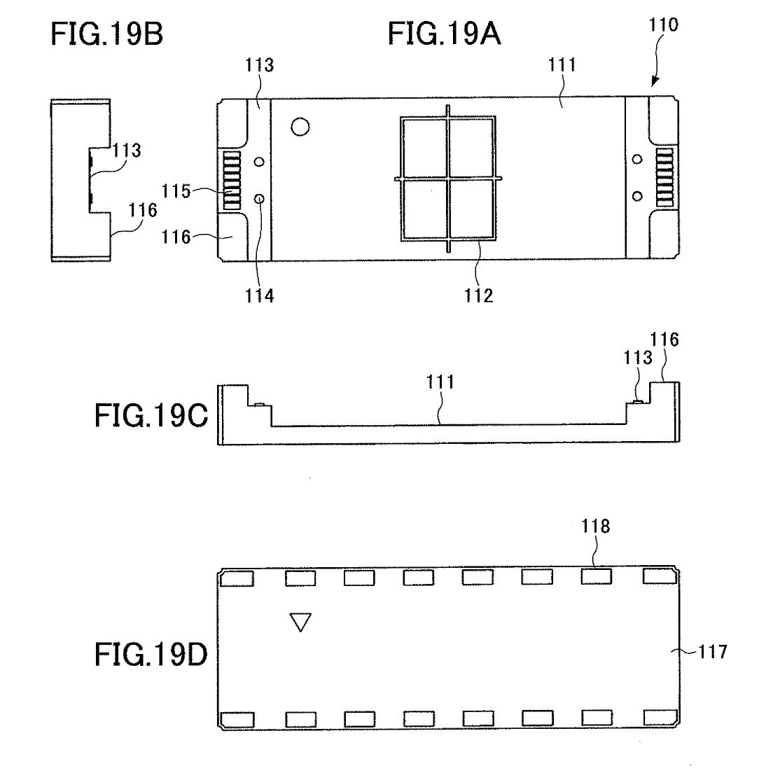

FIGS. 19A-19D are diagrams showing each side of the package 110 of the structure of the embodiment 4. FIG. 19A is a top view of the package 110. As described with reference to FIG. 18A, the upper surface of the package 110 is provided with the bottom part 111 in the center area, the element fixing parts 113 in the outside of the bottom part 111 in the right and left sides, and the attaching parts 116 at the four corners outside the element fixing parts 113. In each side, the attaching parts 116 are provided so as to avoid the terminal pads 115 at the center part of the package 110 in the shorter direction, and to sandwich the terminal pads 115 from both sides, so that electrical connection of the terminal pads 115 is not obstructed. The attaching parts 116 and the terminal pads 115 are arranged on a straight line in the shorter direction of the package 110. Thus, the attaching parts 116 are arranged in both sides of the terminal pads 115 such that they do not interfere with each other. The bonding members 114 are provided adjacent to the terminal pads 115, and are configured such that ultrasonic bonding of the element 44 can be easily performed.

FIG. 19B is a side view of the package 110. As shown in. FIG. 19B, the attaching parts 116 are higher than the element fixing part 113.

FIG. 19C is a front view of the package 110. As shown in FIG. 19C, the package 110 is configured to include three stages of flat planes including the lowest bottom part 111, the intermediate element fixing parts 113 and the attaching parts 116.

FIG. 19D is a bottom view of the package 110. The bottom surface 117 of the package 110 is provided with plural terminals 118.

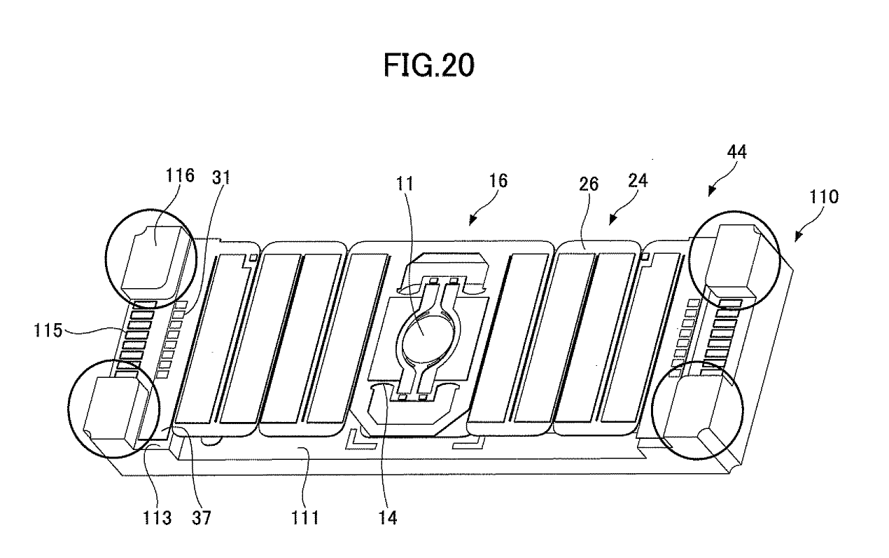

FIG. 20 is a diagram showing the structure of the embodiment 4. FIG. 20 shows a state in which the element 44 is packaged in the package 110. As shown in FIG. 20, the element 44 is provided such that each end is placed on the element fixing part 113, and only the part of the fixing member 37 of the element 44 contacts with the element fixing part 113, so that they are bonded. Accordingly, although the element 44 is fixed by the fixing member 37, the mirror 11, the horizontal driving part 14 including and the horizontal driving beam 14, and the vertical driving part 26 including the vertical driving beam are free. Thus, they can mechanically operate without constraints. Also, the element 44 is surrounded by four attaching parts 116 at the sides so that the element 44 is held while being protected from the outside. Also, the package 110 can be attached to an arbitrary position by connecting the upper surface of the attaching parts 116 to the position.

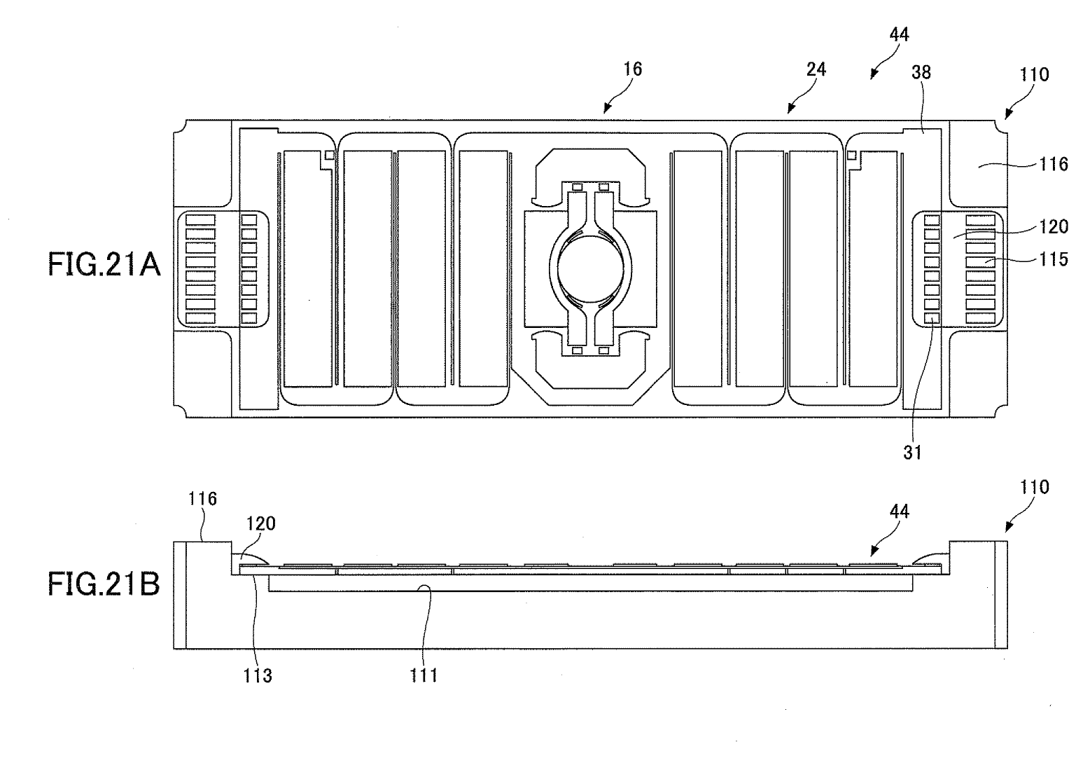

FIGS. 21A and 21B are diagrams showing an example of the structure of the embodiment 4. FIG. 21A is a top view of the structure of the embodiment 4, and FIG. 21B is a front view of the structure of the embodiment 4.

As shown in FIG. 21A, in the structure of the embodiment 4, the element 44 is surrounded by the attaching parts 116 and the terminal pads 115 on two sides. The terminal pads 115 and the electrode pads 31 of the element 44 are adjacent to each other, and are electrically connected by wires not shown in the figure. Since the electrode pad 31 and the terminal pad 115 are adjacent to each other, they are connected with a short wire. Also, a wire protecting resin 120 is formed to cover both of the electrode pads 31 and the terminal pads 115. In FIG. 21A, the wire protecting resin 120 is shown transparently. By providing the wire protecting resin 120, the electrode pads 31, the wires and the terminal pads 115 can be protected from dust and the like in the outside.

FIG. 21B shows a height relationship between the element 44 and the package 110. The element 44 is supported by the element fixing parts 113. The terminal pads 115 and the electrode pads 31 are covered by the wire protecting resin 120.

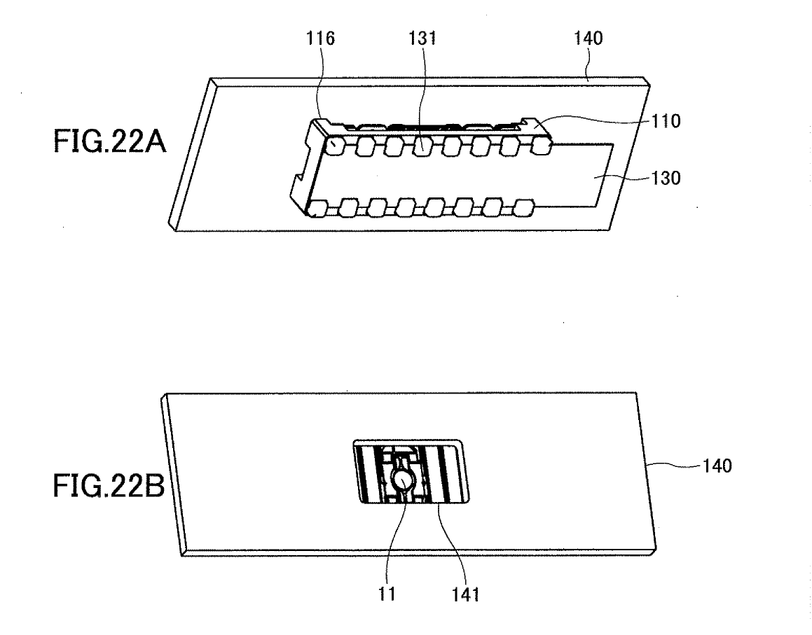

FIGS. 22A and 22B are diagrams showing an example of a state in which the structure of the embodiment 4 is attached to an attachment board. FIG. 22A is a perspective view of the inside of the state in which the structure is attached to the attachment board, and FIG. 22B is a perspective view of the outside of the state in which the structure is attached to the attachment board.

FIG. 22A shows a state in which the package 110 is attached to the attachment board 140. As shown in FIG. 22A, the upper surfaces of the attaching parts 116 are bonded to the attachment board 140 by contacting with the attachment board 140 so that the package 110 is attached to the attachment board 140. A flexible printed circuit 130 is provided on the backside of the package 110, and terminals 131 corresponding to the external connection terminals 118 are provided on the backside of the package 110.

As shown in FIG. 22B, an opening 141 is provided on the attachment board 140 such that a light reflected by the mirror 11 can go out through the opening 141. As mentioned above, the opening 141 through which light can pass is provided on the attachment board 140 to which the package 110 is attached.

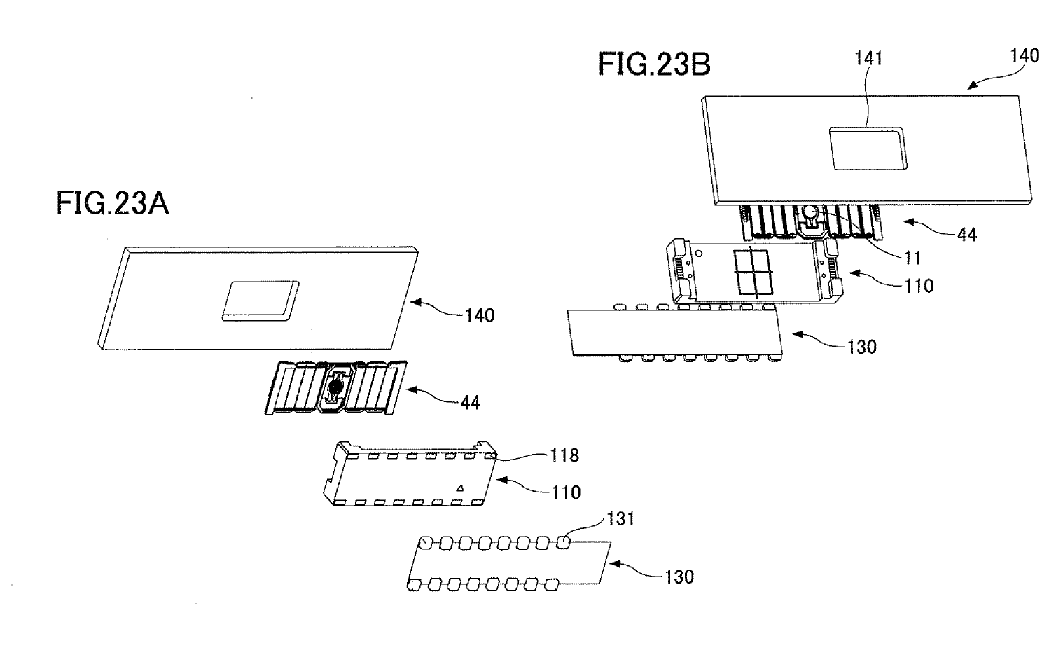

FIGS. 23A and 23B are exploded perspective views of a state in which the structure of the embodiment 4 is attached to the attachment board. FIG. 23A is an exploded perspective view, viewed from the inside, of the state in which the structure of the embodiment 4 is attached to the attachment board. FIG. 23B is an exploded perspective view, viewed from the outside, of the state in which the structure of the embodiment 4 is attached to the attachment board.

As shown in FIG. 23A, the element 44, the package 110, and the flexible printed circuit board 130 are attached to the attachment board 140 in this order. Also, FIG. 23A shows that the terminals 131 of the flexible printed circuit 130 are provided on positions corresponding to the external connection terminals 118 of the package 110.

FIG. 23B is a diagram showing an opposite side of the state of FIG. 23A. As shown in FIG. 23B, the element 44, the package 110, and the flexible printed circuit 130 are sequentially laminated such that the mirror 11 of the element 44 is placed in the opening of the attachment board 140.

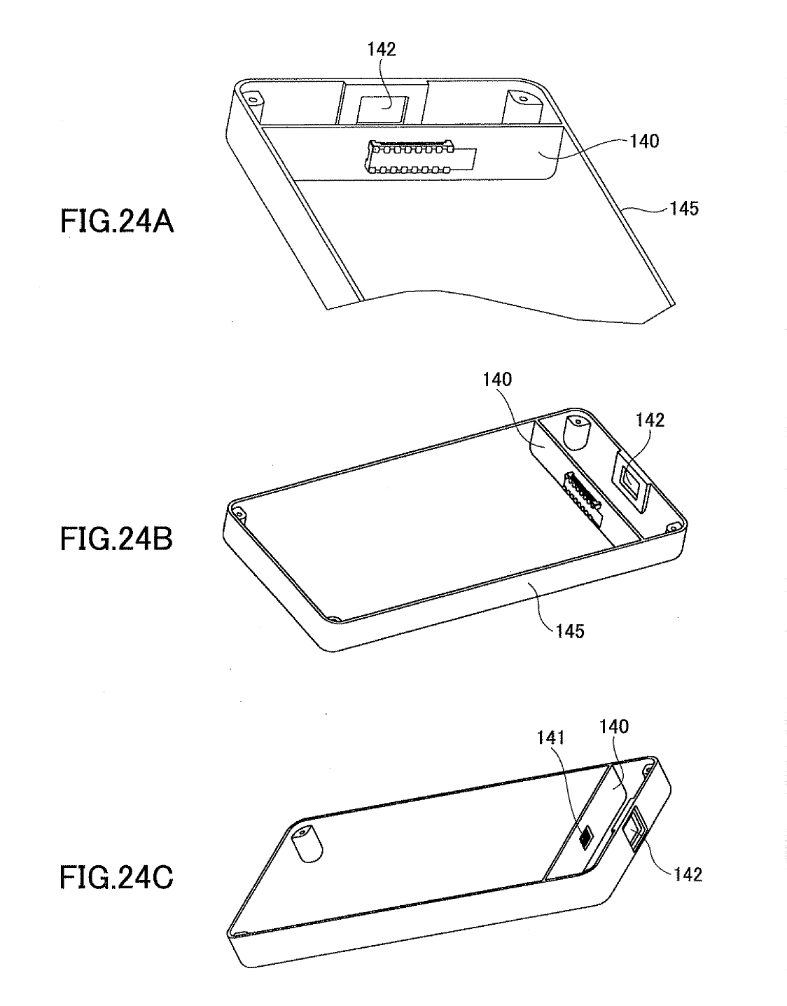

FIGS. 24A-24C are diagrams showing an example in which the structure of the embodiment 4 is attached to a cabinet. FIG. 24A is a diagram of an enlarged view of a part where the structure of the embodiment 4 is attached to the attachment board 140 of the cabinet 145. As shown in FIG. 24A, the attachment board 140 is provided like a partition plate in the inside of the cabinet 145. A cover 142 through which light passes is provided at the end of the cabinet 145. The structure of the embodiment 4 is attached to the attachment board 140 such that the light reflected from the mirror 11 passes through the cover 142. The cabinet 145 may be a cabinet of a projector.

FIG. 24B is a whole perspective view of an example in which the structure of the embodiment 4 is attached to the cabinet. As shown in FIG. 24B, the attachment board 140 in the cabinet 145 is provided at a position closer to the cover 142. By attaching the structure to the attachment board 140, scanning can be performed using light through the cover 142.

FIG. 24C is a backside perspective view of an example in which the structure of the embodiment 4 is attached to the cabinet. As shown in FIG. 24C, the opening 141 of the attachment board 140 and the cover 142 of the cabinet 145 are provided on the same straight line, and the structure is attached such that the mirror 11 is placed at the center of the opening 141.

As mentioned above, according to the structure of the embodiment 4, the element 44 is fixed to the package 110 that does not include a cover, and the package 110 is attached to the cabinet 145 including the opening 141 and the cover 142. Thus, the structure maintaining a compact configuration can be embedded in the cabinet 145, so that it becomes possible to respond to requests of space-saving.

### Embodiment 5

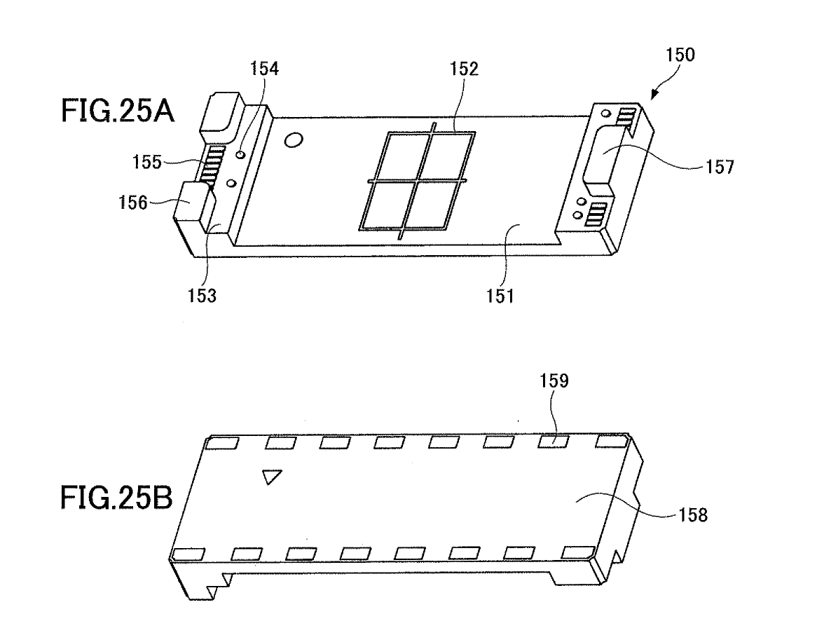

FIGS. 25A and 25B are diagrams showing an example of a package of a structure of the embodiment 5. FIG. 25A is a top perspective view of an example of the package of the structure of the embodiment 5. FIG. 25B is a bottom perspective view of an example of the package of the structure of the embodiment 5.

As shown in FIG. 25A, the package 150 of the embodiment 5 includes a bottom part 151, a positioning mark 152, element fixing parts 153, bonding members 154, terminal pads 155, and attaching parts 156, 157. In the package 150 of the embodiment 5, the configurations of the bottom part 151, the positioning mark 152, element fixing parts 153, bonding members 154, the terminal pads 155 are similar to those of the bottom part 111, the positioning mark 112, element fixing parts 113, bonding members 114, the terminal pads 115 in the embodiment 4. Thus, descriptions of these components are not given.

The package 150 of the structure of the embodiment 5 is different from the package 150 of the structure of the embodiment 4 in that three attaching parts (156, 157), instead of four, are provided in total. That is, the embodiment 5 differs from the embodiment 4 in that two attaching parts 156 in the left side are placed on the corners of the left side, and the attaching part 157 is only one in the right side. The attaching part 157 is placed at a center position in the shorter direction of the package 150, instead of a corner. In the case when the package 150 is attached to the cabinet with three points like the present embodiment, the attaching part 157 is provided in the way mentioned above in order to maintain the balance of force between left and right (front and back in the case of FIG. 25A) of the attaching part 157 that is a vertex. By placing the attaching parts 156, 157 such that the shape formed by the three attaching parts becomes an isosceles triangle as much as possible, the package 150 can be attached stably.

As a result, the terminal pads 155 are placed being distributed in both sides of the attaching part 157. Since the bonding members 154 are provided adjacent to the terminal pads 155, the bonding members 154 are also placed being distributed in both sides of the attaching part 157. As mentioned above, since a part can be held with at least three points, the package 150 may be configured to include three attaching parts. In this case, as shown in FIG. 25A, it is preferable that an area of the joint surface (upper surface) of the attaching part 157 is larger than an area of each of the attaching parts 156.

In this case, the electrode pads 31 of the element in the right side are provided by being distributed to two sides in the shorter direction so as to be adjacent to the terminal pads 155 of the package 150 when the element is placed on the element fixing part 153. Although such an element is not shown in the figure, such an element can be obtained by deforming outward the placement of the right-side electrode pads 31 of the element 44 shown in FIG. 17.

FIG. 25B is a backside perspective view of the package 150 of the structure of the embodiment 5. As shown in the figure, the backside is similar to that of the package 110 of the structure of the embodiment 4. That is, the backside 158 is provided with plural external terminals 159.

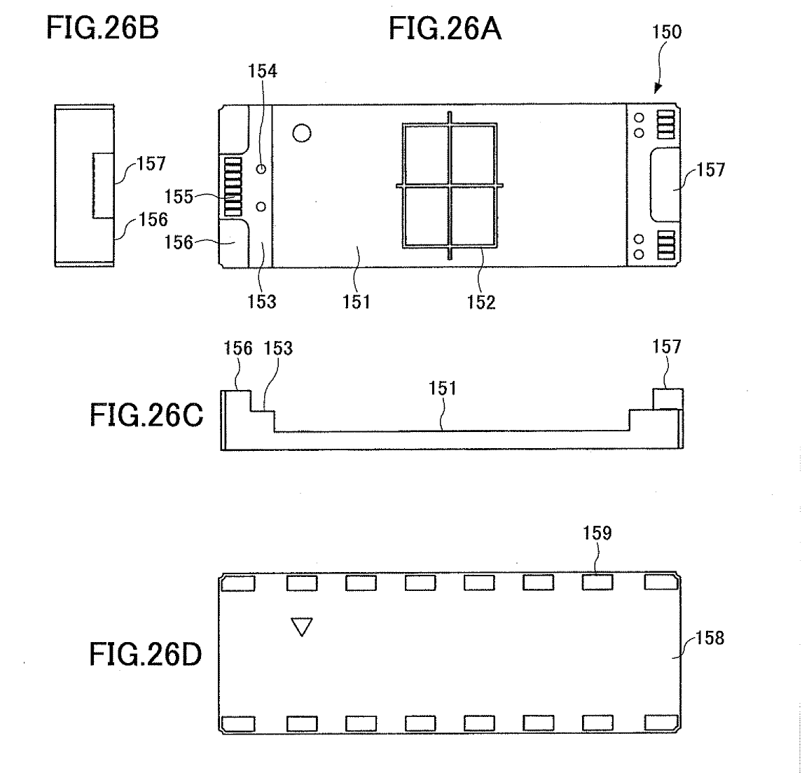

FIGS. 26A-26D are diagrams showing configurations of each surface of the package of the structure in the embodiment 5. FIG. 26A is a top view of the package of the structure in the embodiment 5. As described with reference FIGS. 25A and 25B, in the package 150 of the structure in the embodiment 5, two attaching parts 156 exist at both corners, and one attaching part 157 is placed at the center in the shorter direction of the package 150. Also, the terminal pads 155 are placed on both sides of the attaching part 157 such that the terminal pads 155 sandwich the attaching part 157. Similarly to the package 110 of the embodiment 4, the attaching parts 156 and the terminal pads 155 are placed on a straight line in the shorter direction of the package 150, and the attaching part 157 and the terminal pads 155 are placed on a straight line in the shorter direction of the package 150. Also, the bonding members 154 are provided adjacent to the terminal pads 155. The attaching part 157 is longer than each attaching part 156, such that a joint area of the attaching part 157 becomes large as much as possible. Also, the attaching part 157 is placed so as to maintain the balance between right and left in terms of weight.

FIG. 26B is a side view of the left side of the package of the structure of the embodiment 5. As shown in FIG. 26B, the package is configured such that the attaching part 157 is placed in a gap between the two attaching parts 156.

FIG. 26C is a front view of the package of the structure of the embodiment 5. As shown in FIG. 26C, the attaching part 156 exists on the side surface of the front surface. On the other hand, the attaching part 157 is placed in a rear side.

FIG. 26D is a bottom view of the package of the structure of the embodiment 5. As shown in FIG. 26D, the backside 158 is provided with plural terminals 159 similarly to the package 110 of the structure of the embodiment 4.

The present invention is not limited to the specifically disclosed embodiments, and variations and modifications may be made without departing from the scope of the present invention.

For example, although examples in which the structure is configured as an optical scanning apparatus are described in embodiments 1-5, the structure of the embodiments can be applied to any structure in which an actuator or a sensor body is formed with material such as a semiconductor, the actuator or the sensor body is bonded to a fixing support member formed by material of different thermal expansion coefficient for packaging, and further, the actuator or the sensor body is fixed on a board and ultrasonic bonding is performed for electrical connection. As mentioned above, the present embodiments can be applied to structures such as an actuator or a sensor or the like performing mechanical operation.

What is claimed is:

1. A structure comprising:
a first part including an electrode pad in a predetermined area on a surface;
a second part that is bonded to the first part using an adhesive; and
a board, including a terminal pad, to which the second part is fixed,
wherein the electrode pad and the terminal pad are ultrasonic-bonded, and
the second part includes bosses on an area that overlaps the predetermined area in a bonding surface between the second part and the first part.

2. The structure as claimed in claim 1, wherein three or more bosses are provided on the bonding surface so as to support the first part.

3. The structure as claimed in claim 1, wherein a top end of each of the bosses is shaped like a convex curved surface.

4. The structure as claimed in claim 1, wherein the adhesive has a consistency by which, even though the first part or the second part is thermally-expanded or contracted, the adhesive absorbs stress due to a difference of thermal expansion and contraction to reduce the stress in the first part.

5. The structure as claimed in claim 4, wherein an after-cured Shore hardness of the adhesive is equal to or less than 200.

6. The structure as claimed in claim 1, wherein the second part is transparent, and the adhesive is cured by irradiation of ultraviolet light.

7. The structure as claimed in claim 1, wherein the first part is formed by a semiconductor and the second part is a resin molding part.

8. The structure as claimed in claim 1, wherein the first part is an actuator or a sensor that mechanically operates, and
the second part includes a stopper for shock resistance for the actuator or the sensor.

9. The structure as claimed in claim 8, further comprising a cover configured to cover the first part, the second part and the board,
wherein the cover includes a stopper for shock resistance for the actuator or the sensor.

10. The structure as claimed in claim 8, wherein the first part includes a fixing frame configured to surround a driving part of the actuator or the sensor, and
the fixing frame is bonded to the bonding surface of the second part.

11. The structure as claimed in claim 8, wherein the first part includes a fixing piece configured to support a driving part of the actuator or the sensor with one side, and
the fixing piece is bonded to the bonding surface of the second part.

12. The structure as claimed in claim 8, wherein the first part includes a fixing member configured to support a driving part of the actuator or the sensor by sandwiching the driving part from both sides, and
the fixing member is bonded to the bonding surface of the second part.

13. The structure as claimed in claim 8, wherein the actuator is an optical scanning apparatus configured to perform scanning using a reflected light by fluctuating a mirror around an axis.

14. A structure comprising:
a first part including an electrode pad in a predetermined area on a surface; and
a second part that includes a terminal pad and that is bonded to the first part using an adhesive;
wherein the electrode pad and the terminal pad are ultrasonic-bonded,
the second part includes:
a bonding member on an area that overlaps the predetermined area in a bonding surface between the second part and the first part, and
an attaching part configured to protrude with respect to the first part and to form a plane joint surface that is an upper surface of the attaching part.

15. The structure as claimed in claim 14, wherein the attaching part and the terminal pad are placed on a same straight line.

16. The structure as claimed in claim 15, wherein the terminal pad is placed at a center portion of the second part in a shorter direction of the second part, and
the attaching part is placed so as to sandwich the terminal pad from both sides in the shorter direction.

17. The structure as claimed in claim 16, wherein the attaching part is placed at four corners of the second part.

18. The structure as claimed in claim 14, wherein the first part is formed by a semiconductor, and the second part is formed by ceramics.

19. The structure as claimed in claim 14,
wherein the first part is an actuator or a sensor that mechanically operates, and the first part includes a fixing member configured to support a driving part of the actuator or the sensor by sandwiching the driving part from both sides, and
the second part comprises:
a fixing part to which the fixing member of the first part is bonded; and
a bottom part that is recessed with respect to the fixing part and that does not contact with the driving part.

20. The structure as claimed in claim 19, wherein the actuator is an optical scanning apparatus configured to perform scanning using a reflected light by fluctuating a mirror around an axis.
